(19) United States
(12) Patent Application Publication
(10) Pub. No.: US 2014/0312329 A1
(43) Pub. Date: Oct. 23, 2014

(54) DISPLAY UNIT, METHOD OF MANUFACTURING THE SAME, AND ELECTRONIC APPARATUS

(71) Applicant: Sony Corporation, Tokyo (JP)

(72) Inventors: Takuma Fujii, Aichi (JP); Hirofumi Fujioka, Aichi (JP); Tatsuya Maegawa, Aichi (JP); Tomotaka Nishikawa, Aichi (JP)

(73) Assignee: Sony Corporation, Tokyo (JP)

(21) Appl. No.: 14/251,896

(22) Filed: Apr. 14, 2014

(30) Foreign Application Priority Data
Apr. 19, 2013 (JP) 2013-088634

(51) Int. Cl. H01L 27/32; H01L 51/56

(52) U.S. Cl. CPC H01L 27/3248; H01L 51/56
USPC 257/40; 438/34

(57) ABSTRACT

Provided is a display unit that includes: first electrodes; a metal member provided around the first electrodes; an insulating layer having a first opening on corresponding one of the first electrodes and a second opening on the metal member; an organic light emission layer provided on a surface including a bottom surface of the first opening, except for whole or part of a bottom surface of the second opening; a partition wall arranged in contact with at least the insulating layer, in which the partition wall is formed in a process different from a process of forming the insulating layer; and a second electrode provided in contact with a contact region and a portion above the bottom surface of the first opening in the organic light emission layer, in which the contact region is part of the bottom surface of the second opening.

### CROSS REFERENCE TO RELATED APPLICATIONS

This application claims the benefit of Japanese Priority Patent Application JP 2013-88634 filed on Apr. 19, 2013, the entire contents of which are incorporated herein by reference.

### BACKGROUND

The present technology relates to a display unit including an organic light emission layer for every pixel, to a method of manufacturing the display unit, and to an electronic apparatus including such a display unit.

In recent years, in the field of display units performing image display, a display unit using a current-drive-type light emitting element in which light emission luminance is changed according to a flowing current value such as an organic EL (Electro Luminescence) element has been developed, and commercialization thereof has been promoted. Differently from a liquid crystal element or the like, the organic EL element is a self-light emitting element. Therefore, in a display unit (an organic EL display unit) using the organic EL element, a light source (a backlight) is not necessitated, and therefore, a thinned body and high luminance thereof are achievable easier compared to in a liquid crystal display unit necessitating a light source.

Types of extracting EL light emission of the organic EL display unit outside include a bottom-emission-type to extract EL light emission outside through a support substrate and a top-emission-type to extract EL light emission to the opposite side of the support substrate. In an active-matrix-type bottom-emission-type organic EL display unit, a circuit such as a thin film transistor (TFT) that prevents transmission of EL light emission is arranged under an organic light emitting element, and therefore, a sufficient aperture ratio is less likely to be secured, and light use efficiency is less likely to be improved. In contrast, in the top-emission-type organic EL display unit, EL light emission is extracted to the opposite side of the support substrate, and therefore, the aperture ratio is not subject to a circuit arranged on the support substrate, and high light use efficiency is obtained.

In the top-emission-type organic EL display unit, as an electrode on the light extraction side, a light-transmissive electrically-conductive film is used. The electrically-conductive film is formed in the whole pixel region in the case of an active-matrix-type display unit. Since resistance of the electrically-conductive film is significantly high compared to resistance of general metal materials, display unevenness resulting from voltage drop is easily generated thereby. Therefore, for example, as described in Japanese Unexamined Patent Application Publication No. 2002-318566 (JP2002-318566A), a plurality of auxiliary wirings having low resistance are arranged in the whole pixel region, and such auxiliary wirings are electrically connected to the electrically-conductive film.

### SUMMARY

For example, as described in JP2002-318566A, as a method of electrically connecting an electrically-conductive film to an auxiliary wiring, a method may be contemplated in which part of the top surface of the auxiliary wiring is set to a contact region, and the electrically-conductive film is formed on the contact region. In this case, in order to secure electric connection between the contact region and the electrically-conductive film, it is necessary to locate the formation region of an organic light emission layer on a place far from the contact region so that the organic light emission layer is not formed on the contact region in a process of forming the organic light emission layer before a process of forming the electrically-conductive film. However, in such a case, there have been disadvantages that the formation region of the organic light emission layer is downsized, and the aperture ratio is decreased.

To address the foregoing disadvantages, for example, in Japanese Unexamined Patent Application Publication Nos. 2007-73323 (JP2007-73323A) and 2007-103098 (JP2007-103098A), description is given of a case in which a contact region is formed by wholly forming an organic light emission layer and subsequently removing part thereof However, in such a case, there has been a disadvantage that yield is lowered resulting from a residue in a process of removing the organic light emission layer.

It is desirable to provide a display unit in which a contact region is allowed to be formed without utilizing a process of removing an organic light emission layer and an aperture ratio is allowed to be increased, a method of manufacturing the display unit, and an electronic apparatus including such a display unit.

According to an embodiment of the present technology, there is provided a display unit including: a plurality of first electrodes; a metal member provided around the first electrodes; an insulating layer having a first opening on corresponding one of the first electrodes and a second opening on the metal member; an organic light emission layer provided on a surface including a bottom surface of the first opening, except for whole or part of a bottom surface of the second opening; a partition wall arranged in contact with at least the insulating layer out of part of the bottom surface of the second opening and the insulating layer, the partition wall being formed in a process different from a process of forming the insulating layer; and a second electrode provided in contact with a contact region and in contact with a portion above the bottom surface of the first opening in the organic light emission layer, the contact region being part of the bottom surface of the second opening.

According to an embodiment of the present technology, there is provided an electronic apparatus provided with a display unit. The display unit includes: a plurality of first electrodes; a metal member provided around the first electrodes; an insulating layer having a first opening on corresponding one of the first electrodes and a second opening on the metal member; an organic light emission layer provided on a surface including a bottom surface of the first opening, except for whole or part of a bottom surface of the second opening; a partition wall arranged in contact with at least the insulating layer out of part of the bottom surface of the second opening and the insulating layer, in which the partition wall is formed in a process different from a process of forming the insulating layer; and a second electrode provided in contact with a contact region and in contact with a portion above the bottom surface of the first opening in the organic light emission layer, in which the contact region is part of the bottom surface of the second opening.

In the display unit and the electronic apparatus according to the above-described embodiments of the present technology, the partition wall is arranged in contact with at least the insulating layer out of the part of the bottom surface of the second opening on the metal member and the insulating layer. Thereby, for example, by forming the organic light emission layer by a vapor-phase deposition method (such as an evaporation method), the organic light emission layer is allowed to be formed on the surface including the bottom surface of the first opening while the contact region is formed behind (be hidden behind) the partition wall.

According to an embodiment of the present technology, there is provided a method of manufacturing a display unit, the method including: forming an insulating layer having a first opening on corresponding one of a plurality of first electrodes and a second opening on a metal member, the metal member being provided around the first electrodes; forming, by a vapor-phase diffusion method, a partition wall to be in contact with at least the insulating layer out of part of a bottom surface of the second opening and the insulating layer; forming, by a vapor-phase deposition method, an organic light emission layer on a surface including a bottom surface of the first opening, except for whole or part of the bottom surface of the second opening; and forming, by a vapor-phase deposition method in which deflection of an incident angle is decreased compared to the vapor-phase deposition method used upon forming the organic light emission layer, a second electrode in contact with a contact region and in contact with a portion above the bottom surface of the first opening in the organic light emission layer, the contact region being part of the bottom surface of the second opening.

In the method of manufacturing the display unit according to the above-described embodiment of the present technology, by forming the organic light emission layer by the vapor-phase deposition method, the organic light emission layer is allowed to be formed on the surface including the bottom surface of the first opening while the contact region is formed behind (be hidden behind) the partition wall.

According to the display unit, the manufacturing method thereof, and the electronic apparatus in the above-described embodiments of the present technology, the partition wall is arranged in contact with at least the insulating layer out of the part of the bottom surface of the second opening on the metal member and the insulating layer. Therefore, the organic light emission layer is allowed to be formed on the surface including the bottom surface of the first opening while the contact region is formed behind (be hidden behind) the partition wall. Therefore, the contact region is allowed to be formed without utilizing a process of removing the organic light emission layer, and the aperture ratio is allowed to be increased.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a diagram illustrating a schematic configuration of a display unit according to an embodiment of the present technology.

FIG. 2 is a diagram illustrating an example of a circuit configuration in each pixel.

FIG. 3 is a view illustrating an example of a cross-sectional configuration in a row direction of three pixels aligned in the row direction.

FIG. 4 is a view illustrating an example of a cross-sectional configuration in a column direction of one pixel and the vicinity thereof.

FIG. 5 is an enlarged view illustrating a cross-sectional configuration of the vicinity of an auxiliary wiring in FIG. 4.

FIG. 6 is a diagram illustrating an example of a layout of a pixel electrode, the auxiliary wiring, a partition wall, and a contact region in a pixel region.

FIG. 7 is a diagram illustrating an example of a layout of an organic light emission layer, the partition wall, and the contact region in the pixel region.

FIG. 8A is a view illustrating an example of a planar shape of the partition wall.

FIG. 8B is a view illustrating an example of a planar shape of the partition wall.

FIG. 8C is a view illustrating an example of a planar shape of the partition wall.

FIG. 8D is a view illustrating an example of a planar shape of the partition wall.

FIG. 8E is a view illustrating an example of a planar shape of the partition wall.

FIG. 8F is a view illustrating an example of a planar shape of the partition wall.

FIG. 9 is a cross-sectional view illustrating an example of a series of processes of manufacturing the display unit.

FIG. 10 is a cross-sectional view illustrating an example of a process following the process of FIG. 9.

FIG. 11 is a cross-sectional view illustrating an example of a process following the process of FIG. 10.

FIG. 12 is a diagram illustrating an example of a layout of a pixel electrode, an auxiliary wiring, and a contact region in a pixel region of a display panel according to a comparative example.

FIG. 13 is a diagram illustrating an example of a layout of an organic light emission layer and a contact region in the pixel region of the display panel according to the comparative example.

FIG. 14 is a view illustrating a first modification of the cross-sectional configuration in the column direction of one pixel and the vicinity thereof.

FIG. 15 is a cross-sectional view illustrating an example of a series of processes of manufacturing the display unit including the cross-sectional configuration of FIG. 14.

FIG. 16 is a cross-sectional view illustrating an example of a process following the process of FIG. 15.

FIG. 17 is a cross-sectional view illustrating an example of a process following the process of FIG. 16.

FIG. 18 is a cross-sectional view illustrating another example of a process following the process of FIG. 15.

FIG. 19 is a cross-sectional view illustrating an example of a process following the process of FIG. 18.

FIG. 20 is a view illustrating a second modification of the cross-sectional configuration in the column direction of one pixel and the vicinity thereof.

FIG. 21 is a view illustrating a third modification of the cross-sectional configuration in the column direction of one pixel and the vicinity thereof.

FIG. 22A is a cross-sectional view illustrating an example of a series of processes of manufacturing the display unit including the cross-sectional configuration of FIG. 21.

FIG. 22B is a cross-sectional view illustrating an example of a process following the process of FIG. 22A.

FIG. 23A is a cross-sectional view illustrating another example of a series of processes of manufacturing the display unit including the cross-sectional configuration of FIG. 21.

FIG. 23B is a cross-sectional view illustrating an example of a process following the process of FIG. 23A.

FIG. 23C is a cross-sectional view illustrating an example of a process following the process of FIG. 23B.

FIG. 23D is a cross-sectional view illustrating an example of a process following the process of FIG. 23C.

FIG. 24 is a view illustrating a fourth modification of the cross-sectional configuration in the column direction of one pixel and the vicinity thereof.

FIG. 25 is a view illustrating a fifth modification of the cross-sectional configuration in the column direction of one pixel and the vicinity thereof.

FIG. 26 is a view illustrating a sixth modification of the cross-sectional configuration in the column direction of one pixel and the vicinity thereof.

FIG. 27 is a view illustrating a seventh modification of the cross-sectional configuration in the column direction of one pixel and the vicinity thereof.

FIG. 28 is a view illustrating a first modification of the cross-sectional configuration in the row direction of the three pixels aligned in the row direction.

FIG. 29 is a view illustrating a second modification of the cross-sectional configuration in the row direction of the three pixels aligned in the row direction.

FIG. 30 is a perspective view illustrating an appearance of Application example 1 of the display unit according to any of the foregoing embodiment and the modifications.

FIG. 31A is a perspective view illustrating an appearance viewed from the front side of Application example 2.

FIG. 31B is a perspective view illustrating an appearance viewed from the rear side of Application example 2.

FIG. 32 is a perspective view illustrating an appearance of Application example 3.

FIG. 33 is a perspective view illustrating an appearance of Application example 4.

FIG. 34A is an elevation view of Application example 5 unclosed, FIG. 34B is a side view thereof, FIG. 34C is an elevation view of Application example 5 closed, FIG. 34D is a left side view thereof, FIG. 34E is a right side view thereof, FIG. 34F is a top view thereof, and FIG. 34G is a bottom view thereof.

### DETAILED DESCRIPTION

An embodiment of the present technology will be described in detail below with reference to the drawings. The description will be given in the following order.
1. Embodiment (a display unit)
2. Modifications (display units)
3. Application Examples (electronic apparatuses)

### 1. Embodiment

### [Configuration]

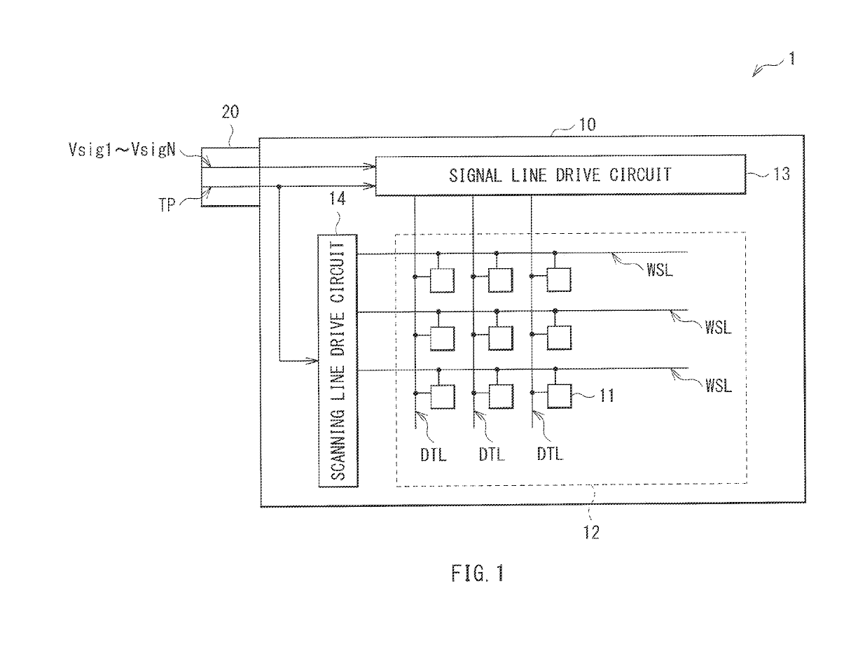

FIG. 1 illustrates a schematic configuration of a display unit 1 according to an embodiment of the present technology. The display unit 1 may include, for example, a display panel 10 and a flexible printed circuit (FPC) 20 (hereinafter referred to as “FPC 20”) connected to the display panel 10.

For example, the display panel 10 may be configured to display an image based on image signals Vsig1 to VsigN and a synchronization signal TP inputted from outside. The display panel 10 may have for example, a pixel region 12 in which a plurality of pixels 11 are formed in a matrix pattern, a signal line drive circuit 13, and a scanning line drive circuit 14. For example, the display panel 10 may be configured to display an image based on the image signals Vsig1 to VsigN when the respective pixels 11 are active-driven by the signal line drive circuit 13 and the scanning line drive circuit 14.

The display panel 10 has a plurality of writing lines WSL extending in a row direction and a plurality of signal lines DTL extending in a column direction. The pixels 11 are provided correspondingly to intersections between the signal lines DTL and the writing lines WSL. The respective signal lines DTL are connected to output terminals of the signal line drive circuit 13. The respective writing lines WSL are connected to output terminals of the scanning line drive circuit 14.

The signal line drive circuit 13 may be configured, for example, to supply the analog image signals Vsig1 to VsigN for one horizontal line inputted from outside through the FPC 20 as a signal voltage to the respective pixels 11. Specifically, the signal line drive circuit 13 may be configured, for example, to supply the analog image signals Vsig1 to VsigN for one horizontal line to the respective pixels 11 configuring one horizontal line selected by the scanning line drive circuit 14 through the signal lines DTL.

The scanning line drive circuit 14 may be configured, for example, to select drive-intended pixels 11 according to the synchronization signal TP inputted from outside through the FPC 20. Specifically, the scanning line drive circuit 14 is configured, for example, to select one row of pixels 11 out of the plurality of pixels 11 arranged in a matrix pattern as drive-intended pixels by applying a selection pulse to pixel circuits (described later) of the pixels 11 through the scanning line WSL. In the drive-intended pixels 11, one horizontal line is displayed according to a signal voltage supplied from the signal line drive circuit 13. As described above, the scanning line drive circuit 14 is configured, for example, to sequentially scan for every one horizontal line in a manner of time division, and perform display over the whole pixel region 12.

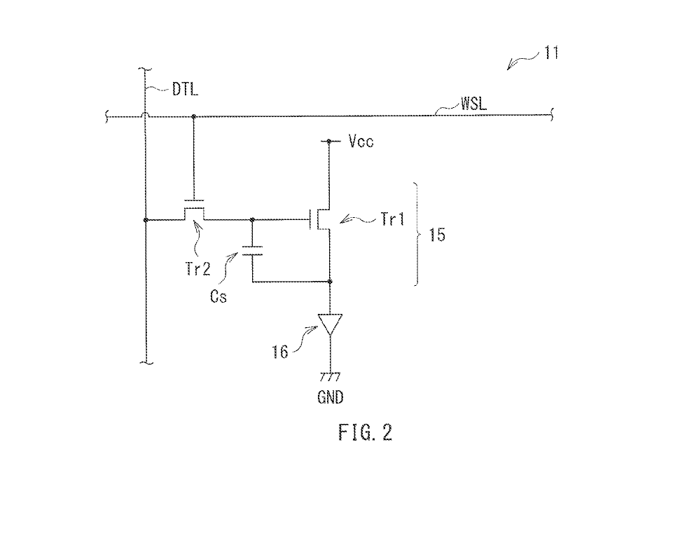

FIG. 2 illustrates an example of a circuit configuration in the pixel 11. Each of the pixels 11 may have, for example, the pixel circuit 15 and an organic EL element 16. The organic EL element 16 may have, for example, a configuration in which an anode electrode, an organic light emission layer, and a cathode electrode are laminated in order. The pixel circuit 15 may be configured, for example, of a drive transistor Tr1, a writing transistor Tr2, and a holding capacitor Cs, and has a 2Tr1C circuit configuration. The writing transistor Tr2 is configured to control application of a signal voltage to a gate of the drive transistor Tr1. Specifically, the writing transistor Tr2 is configured to sample a voltage of the signal line DTL and write the resultant on the gate of the drive transistor Tr1. The drive transistor Tr1 is configured to drive the organic EL element 16, and is connected in series to the organic EL element 16. The drive transistor Tr1 is configured to control a current flowing through the organic EL element 16 according to a magnitude of a voltage written by the writing transistor Tr2. The holding capacitor Cs is configured to hold a predetermined voltage between the gate and a source of the drive transistor Tr1. It is to be noted that the pixel circuit 15 may have a circuit configuration obtained by adding various capacitors and/or a transistor to the foregoing 2Tr1C circuit, or may have a circuit configuration different from the foregoing 2Tr1C circuit configuration.

Each of the drive transistor Tr1 and the writing transistor Tr2 may be formed, for example, of an n-channel MOS-type thin film transistor (TFT). It is to be noted that the type of TFT is not particularly limited, and, for example, may be an inversely staggered structure (a so-called bottom gate type) or a staggered structure (a top gate type). Further, each of the drive transistor Tr1 and the writing transistor Tr2 may be formed, for example, of a p-channel MOS-type TFT.

A gate of the writing transistor Tr2 is connected to the scanning line WSL. One of a source and a drain of the writing transistor Tr2 is connected to the signal line DTL, and the other thereof is connected to the gate of the drive transistor Tr1. One of the source and a drain of the drive transistor Tr1 is connected to an electric power line Vcc, and the other thereof is connected to the anode of the organic EL element 16. One end of the holding capacitor Cs is connected to the gate of the drive transistor Tr1, and the other end of the holding capacitor Cs is connected to a terminal on the organic EL element 16 side out of the source and the drain of the drive transistor Tr1.

For example, as illustrated in FIG. 2, the display panel 10 may further have a ground line GND connected to the cathode of the organic EL element 16. The ground line GND is electrically connected to an external circuit having a ground electric potential. The ground line GND may be, for example, a sheet-like electrode formed over the whole pixel region 12. The ground line GND may be a strip-like electrode formed in the shape of a strip correspondingly to a pixel row or a pixel column.

Each of the pixels 11 corresponds to a minimum unit point configuring a screen on the display panel 10. The display panel 10 is a color display panel, and the pixels 11 may correspond to sub pixels emitting monochromatic light such as red light, green light, and blue light. The pixels 11 may correspond to sub pixels emitting monochromatic light such as red light, green light, blue light, and white light; or may correspond to sub pixels emitting monochromatic light such as red light, green light, blue light, and yellow light. Description will be given below of the pixels 11 in a case where each of the pixels 11 corresponds to a sub pixel emitting monochromatic light of red, green, or blue.

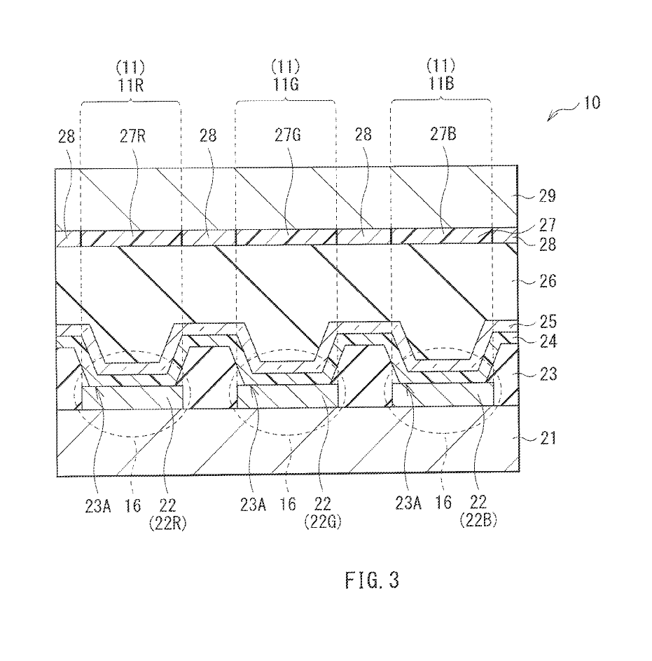

FIG. 3 illustrates an example of a cross-sectional configuration in a row direction of three pixels 11 aligned in the row direction. In this embodiment, a pixel (a color pixel) as color display is configured of three pixels 11 having different light emission colors. The three pixels 11 included in the color pixel are a pixel 11R emitting red light, a pixel 11G emitting green light, and a pixel 11B emitting blue light. In each color pixel, the three pixels 11 are aligned in the row direction in line, and, for example, may be aligned from the left direction to the right direction in the figure in the order from the pixel 11R, the pixel 11G, and the pixel 11B. Further, the respective color pixels are arranged in a matrix pattern, and two pixels 11 adjacent to each other in a column direction emit the same color light. That is, pixel arrangement in the pixel region 12 is a so-called stripe arrangement.

The display panel 10 may have, for example, the plurality of organic EL elements 16 on a circuit substrate 21 in which the pixel circuits 15 are formed. The organic EL element 16 has a structure in which an organic light emission layer 24 is sandwiched between a pixel electrode 22 and a transparent electrode 25. That is, the pixel electrode 22 and the transparent electrode 25 are provided in the pixel region 12. The pixel electrode 22 corresponds to a specific example of “a first electrode” in one embodiment of the present technology. The transparent electrode 25 corresponds to a specific example of “a second electrode” in one embodiment of the present technology. The pixel electrode 22 is formed on the circuit substrate 21 side with respect to the organic light emission layer 24, and may serve, for example, as the anode electrode of the organic EL element 16. Each of the pixel electrodes 22 is independently provided for every pixel 11. The plurality of pixel electrodes 22 are arranged in a matrix pattern in one plane inside the display panel 10. The pixel electrode 22 is made of a metal material, and also serves as a reflecting mirror that reflects light emitted from the organic light emission layer 24 on the transparent electrode 25 side.

In contrast, the transparent electrode 25 is formed on the side opposite to the circuit substrate 21 side with respect to the organic light emission layer 24, and may serve, for example, as the cathode electrode of the organic EL element 16. The transparent electrode 25 is a sheet-like electrode formed over the whole pixel region 12. The transparent electrode 25 may be a strip-like electrode formed in the shape of a strip correspondingly to a pixel row or a pixel column. The transparent electrode 25 may correspond, for example, to the foregoing ground line GND. The transparent electrode 25 serves as a common electrode in the respective pixels 11.

The transparent electrode 25 is an electrode through which visible light is transmitted, and is made of a light-transmissive electrically-conductive material. Examples of the light-transmissive electrically-conductive material may include metals and alloys that contain one or more of Mg, Ag, Al, Cu, and Au. The light-transmissive electrically-conductive material may be a material in which one or both of Ca and Li is contained in any of the foregoing metals or any of the foregoing alloys. In the case where one or both of Ca and Li is contained in any of the foregoing metals or any of the foregoing alloys, light transmissibility (transparency) of the electrically-conductive material is improved. For example, the light-transmissive electrically-conductive material may be made of any of metals and alloys that contains one or both of Ca and Li, Mg, and Ag. In the case where the transparent electrode 25 is made of any of the foregoing metals or any of the foregoing alloys, the transparent electrode 25 may be formed by a vapor-phase deposition method (such as an evaporation method). The light-transmissive electrically-conductive material may be made, for example, of ITO, IZO, or the like. In the case where the transparent electrode 25 is made of ITO or IZO, the transparent electrode 25 may be formed by a vapor-phase deposition method (such as a sputtering method).

The organic light emission layer 24 may have, for example, a hole injection layer to improve hole injection efficiency, a hole transport layer to improve efficiency to transport holes to the light emission layer, a light emission layer to generate light due to electron-hole recombination, and an electron transport layer to improve efficiency to transport electrons to the light emission layer in the order from the pixel electrode 22 side. The organic light emission layer 24 emits white light. The foregoing light emission layer may have, for example, a laminated structure including a light emission layer emitting red light, a light emission layer emitting green light, and a light emission layer emitting blue light in the order from the pixel electrode 22 side. The hole injection layer, the hole transport layer, the light emission layer, and the electron transport layer may be made, for example of a material described in Japanese Unexamined Patent Application Publication No. 2012-209095. The organic light emission layer 24 may be formed by a vapor-phase deposition method (such as an evaporation method).

For example, as illustrated in FIG. 3, the display panel 10 may have an insulating layer 23 in a gap between adjacent organic EL elements 16. The insulating layer 23 insulates and separates adjacent pixel electrodes 22 from each other, and is a pixel-defining film to accurately form a desired shape of a light emission region. The insulating layer 23 is formed on the same surface as that of the pixel electrode 22, and buries in surroundings of the pixel electrode 22. The top surface of the insulating layer 23 is located higher than the top surface of the pixel electrode 22. The insulating layer 23 has an opening (a pixel opening 23A) defining the shape of the light emission region in a location opposed to the top surface of the pixel electrode 22. The pixel opening 23A corresponds to a specific example of “a first opening” in one embodiment of the present technology. The organic light emission layer 24 is formed at least inside the pixel opening 23A, and is in contact with a portion exposed on the bottom surface of the pixel opening 23A out of the top surface of the pixel electrode 22. The transparent electrode 25 is also formed at least inside the pixel opening 23A, and is in contact with at least a portion above the pixel opening 23A out of the top surface of the organic light emission layer 24. The insulating layer 23 is made of a resin material capable of transmitting visible light, and may be made, for example, of polyimide.

The display panel 10 may have, for example, an opposing substrate 29 in a position opposed to the circuit substrate 21 with a predetermined gap in between. The opposing substrate 29 is configured to protect the pixel circuit 15, the organic EL element 16, and the like, and may be made, for example, of a glass substrate or a light-transmissive resin substrate. The display panel 10 may have, for example, a color filter 27 and a black matrix 28 on the rear surface (the surface on the circuit substrate 21 side) of the opposing substrate 29.

The color filter 27 is arranged in a position opposed to the pixel electrode 22, and is arranged at least inside the pixel 11. The color filter 27 is configured to selectively transmit light emitted from the organic light emission layer 24 in desired wavelength band. In the color filter 27, for example, wavelength band of selectively transmitted light is made different for each of the pixel 11R, the pixel 11G, and the pixel 11B. For example, the color filter 27 may have a red filter 27R selectively transmitting red light in the pixel 11R, a green filter 27G selectively transmitting green light in the pixel 11G, and a blue filter 27B selectively transmitting blue light in the pixel 11B.

The black matrix 28 is arranged in a position not opposed to the pixel electrode 22 (that is, around the pixel 11), and may be arranged, for example, in the same plane as that of the color filter 27. The black matrix 28 is configured to block light leaking from around the pixel 11 in the pixel region 12, and may contain, for example, a material absorbing light emitted from the organic light emission layer 24.

The display panel 10 may have, for example, an insulating layer 26 in the gap between the circuit substrate 21 and the opposing substrate 29. The insulating layer 26 is formed to be buried in the gap between the circuit substrate 21 and the opposing substrate 29. The insulating layer 26 may be arranged, for example, between the transparent electrode 25 and the color filter 27 and between the transparent electrode 25 and the black matrix 28, and may be in contact with the transparent electrode 25, the color filter 27, and the black matrix 28. The insulating layer 26 is made of a resin material capable of transmitting visible light, and may be made, for example, of polyimide.

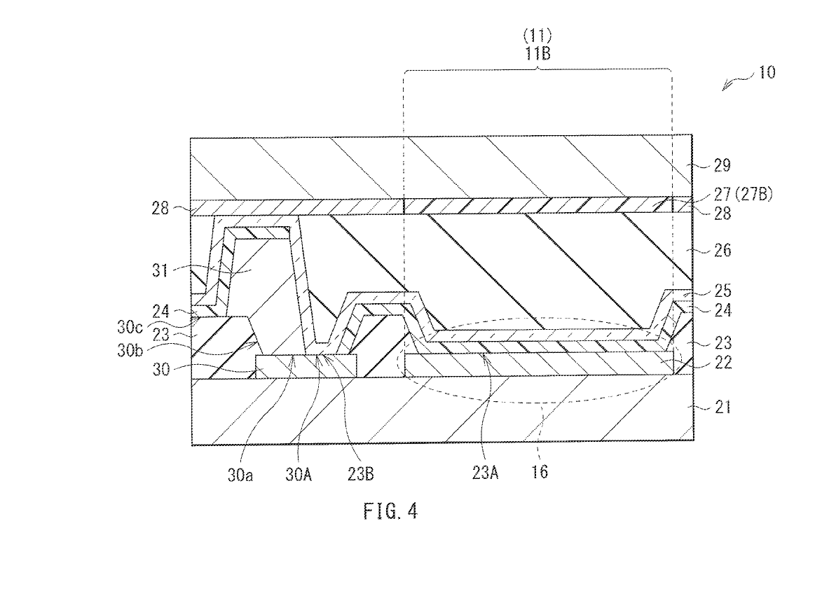

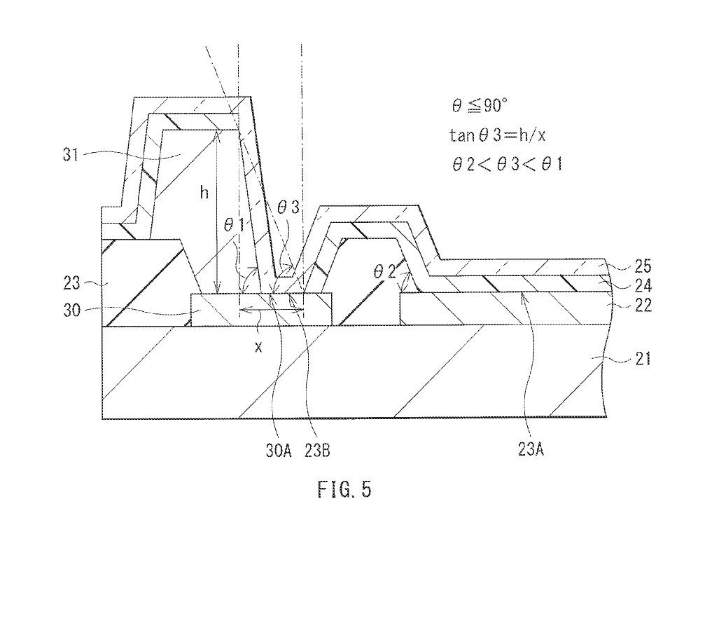

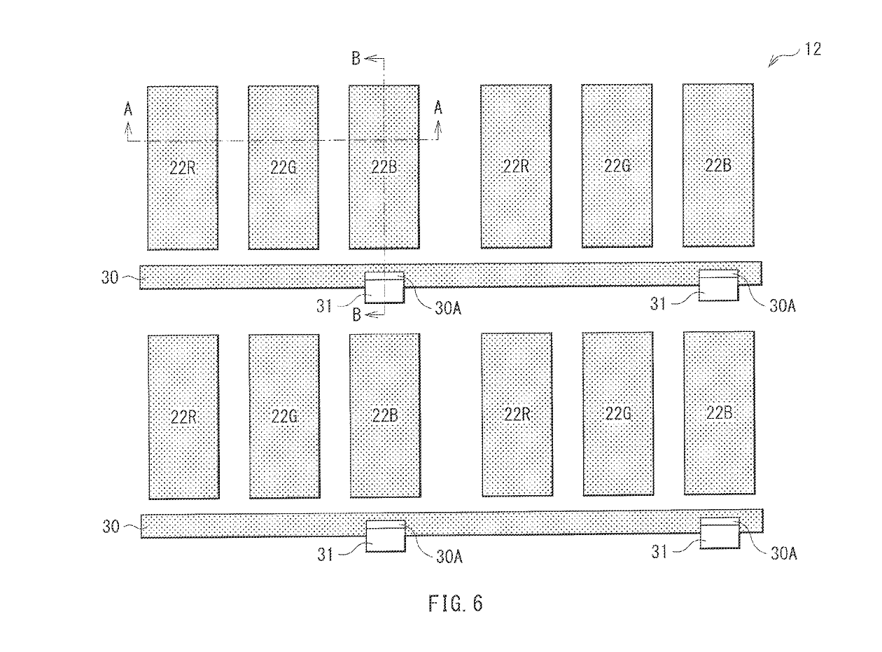

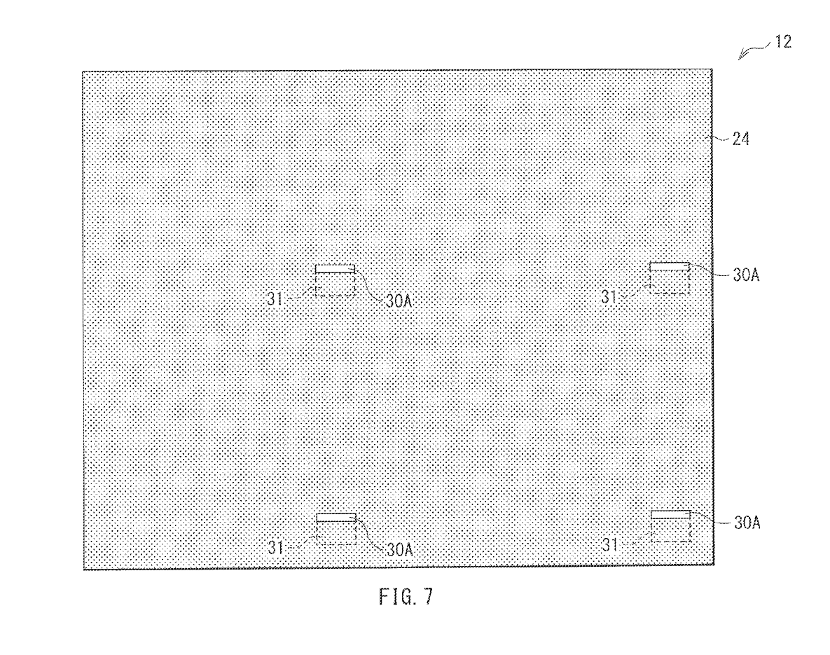

FIG. 4 illustrates an example of a cross-sectional configuration in the column direction of one pixel 11 and the vicinity thereof. FIG. 5 illustrates an enlarged cross-sectional configuration of the vicinity of an auxiliary wiring 30 (described later) in FIG. 4. FIG. 6 illustrates an example of a layout of the pixel electrodes 22 (22R, 22G, and 22B), the auxiliary wiring 30, a partition wall 31 (described later), and a contact region 30A (described later) in the pixel region 12. It is to be noted that the cross section of FIG. 3 corresponds to a cross section taken along a line A-A of FIG. 6. The cross sections of FIG. 4 and FIG. 5 correspond to a cross section taken along a line B-B of FIG. 6. FIG. 7 illustrates an example of a layout of the organic light emission layer 24, the partition wall 31, and the contact region 30A in the pixel region 12.

The display panel 10 may have, for example, a plurality of auxiliary wirings 30 around the pixel 11 (or the pixel electrode 22). The auxiliary wiring 30 is provided adjacently to the pixel electrode 22, and is provided in a gap between two adjacent pixel electrodes 22 out of the plurality of pixel electrodes 22. The auxiliary wiring 30 corresponds to a specific example of “a metal member” in one embodiment of the present technology. The auxiliary wiring 30 is for decreasing voltage drop resulting from large electric resistance of the transparent electrode 25. The auxiliary wiring 30 is formed on the circuit substrate 21, and may be arranged, for example, in the same plane as that of the pixel electrode 22. The auxiliary wiring 30 may be, for example, formed together with the pixel electrode 22 in a manufacturing process, and may be made of the same material as that of the pixel electrode 22 and have the same thickness as that of the pixel electrode 22. The auxiliary wiring 30 may be made, for example, of any of metals and alloys that contains one or more materials of Au, Pt, Ni, Cr, Cu, W, Mo, and Ag. The plurality of auxiliary wirings 30 are arranged around the pixel 11 in a state of being insulated from the pixel electrode 22. The plurality of auxiliary wirings 30 may, for example, extend in the row direction in a gap between two pixels 11 adjacent to each other in the column direction.

The auxiliary wiring 30 may be formed in a plane different from that of the pixel electrode 22, and may be formed, for example, in a layer lower than that of the pixel electrode 22. However, in this case, for example, the display panel 10 may preferably have pad-like plurality of auxiliary electrodes that are electrically connected to the auxiliary wiring 30 around the pixel 11 (or the pixel electrode 22). The auxiliary electrode is provided adjacently to the pixel electrode 22, and is provided in a gap between two adjacent pixel electrodes 22 out of the plurality of pixel electrodes 22. The auxiliary electrode corresponds to a specific example of “a metal member” in one embodiment of the present technology. The auxiliary electrode is for decreasing voltage drop resulting from large electric resistance of the transparent electrode 25. The auxiliary electrode is formed on the circuit substrate 21, and may be arranged, for example, in the same plane as that of the pixel electrode 22. The auxiliary electrode may be formed, for example, together with the pixel electrode 22 in a manufacturing process, and may be made of the same material as that of the pixel electrode 22 and have the same thickness as that of the pixel electrode 22. The auxiliary electrode may be made, for example, of any of metals and alloys that contains one or more materials of Au, Pt, Ni, Cr, Cu, W, Mo, and Ag. The plurality of auxiliary electrodes are arranged around the pixel 11 in a state of being insulated from the pixel electrode 22. The plurality of auxiliary electrodes may be arranged, for example, in a gap between two pixels 11 adjacent to each other in the column direction.

The insulating layer 23 insulates and separates the pixel electrode 22 from the auxiliary wiring 30 adjacent to such a pixel electrode 22, and is buried in the surroundings of the auxiliary wiring 30. The top surface of the insulating layer 23 is located higher than the top surface of the auxiliary wiring 30. The insulating layer 23 has an opening (a contact opening 23B) for electrically connecting the auxiliary wiring 30 to the transparent electrode 25 in a position opposed to the top surface of the auxiliary wiring 30. The contact opening 23B corresponds to a specific example of “a second opening” in one embodiment of the present technology. The transparent electrode 25 is also formed inside the contact opening 23B, and is in contact with part of a portion exposed on the bottom surface of the contact opening 23B out of the top surface of the auxiliary wiring 30. In the following description, out of the bottom surface of the contact opening 23B, the portion in contact with the transparent electrode 25 is referred to as the contact region 30A. The contact region 30A is a region not covered with the insulating layer 23 and the after-described partition wall 31 out of the top surface of the auxiliary wiring 30. It is to be noted that, in the case where the foregoing auxiliary electrode is provided, “the auxiliary wiring 30” will be read as “the auxiliary electrode” on and after this paragraph.

The display panel 10 has the partition wall 31 in a position adjacent to each contact region 30A. The contact region 30A exists between the partition wall 31 and the pixel electrode 22. That is, the partition wall 31 is arranged oppositely to the pixel electrode 22 with the contact region 30A in between in the plane. The contact region 30A and the partition wall 31 may be arranged, for example, in a gap between two pixels 11 (or two pixel electrodes 22) adjacent to each other in the column direction. It is to be noted that, in this embodiment, the contact region 30A and the partition wall 31 may be arranged, for example, in a gap between two color pixels adjacent to each other in the row direction. The partition wall 31 is used for selectively forming the organic light emission layer 24 in the plane in a manufacturing process. The partition wall 31 may be in contact with the opposing substrate 29 or the black matrix 28 with the transparent electrode 25 also formed on the top surface of the partition wall 31 in between. In this case, for example, the partition wall 31 may also have a role to support the opposing substrate 29. It is to be noted that the partition wall 31 may be formed low to the degree that the transparent electrode 25 also formed on the top surface of the partition wall 31 is not in contact with the opposing substrate 29 or the black matrix 28.

The partition wall 31 is in contact with part of a portion exposed on the bottom surface of the contact opening 23B out of the top surface of the auxiliary wiring 30. Specifically, the partition wall 31 is in contact with a region other than the contact region 30A out of the bottom surface of the contact opening 23B. For example, as described above, in the case where the organic light emission layer 24 is formed by a vapor-phase deposition method (such as an evaporation method), the organic light emission layer 24 is formed on the whole surface of the pixel region 12 except for a region (the contact region 30A) located behind the partition wall 31. Although depending on usage of the partition wall 31 in a manufacturing method, the organic light emission layer 24 may be formed on (in contact with) part of the bottom surface of the contact opening 23B in some cases, or the organic light emission layer 24 may not be formed on (not in contact with) the bottom surface of the contact opening 23B in some cases. That is, the organic light emission layer 24 is formed on the surface including a region (a second region) exposed on the bottom surface of the pixel opening 23A out of the top surface of the pixel electrode 22 except for all or part of a section (a first region) exposed on the bottom surface of the contact opening 23B. Therefore, the partition wall 31 is in contact with part of a non-contact region 30a as a region not in contact with the organic light emission layer 24 out of the bottom surface of the contact opening 23B. Strictly speaking, the partition wall 31 is in contact with a region except for the contact region 30A and a region in contact with the organic light emission layer 24 out of the bottom surface of the contact opening 23B.

The partition wall 31 is further in contact with the insulating layer 23. Specifically, the partition wall 31 is in contact with a region (an adjacent side surface 30b) adjacent to the non-contact region 30a out of a side surface of the contact opening 23B, and is in contact with a region (an adjacent top surface 30c) adjacent to the adjacent side surface 30b out of the top surface of the insulating layer 23. That is, the partition wall 31 is in contact with all three locations of part of the non-contact region 30a, the adjacent side surface 30b, and the adjacent top surface 30c. The partition wall 31 is formed in a process different from that of the insulating layer 23. An interface exists between the partition wall 31 and the insulating layer 23.

The partition wall 31 may be made, for example, of a metal material, an inorganic material, or an organic material. Examples of the metal materials capable of being used for the partition wall 31 may include one of Al, Ag, Mo, Ti, W, and Cu, and an alloy containing one or more thereof. Further, examples of the metal materials capable of being used for the partition wall 31 may include ITO and IZO. In the case where the partition wall 31 is made of any of the foregoing metal materials, for example, the partition wall 31 may be formed by forming a film made of the metal material by a sputtering method, and subsequently shaping the resultant in a predetermined shape by a photolithography method and a wet etching method. The partition wall 31 may be formed, for example, as follows. First, Al and Mo are laminated in this order by a sputtering method. Subsequently, a resist having a desired pattern that is shaped in a predetermined shape by a photolithography method is formed thereon. Next, with the use of the resist as a mask, the laminated film of Al and Mo is soaked in a mixed acid of phosphoric acid, nitric acid, and acetic acid to perform etching. Thereafter, the resist is removed by exposing to O₂ plasma or dissolving the resist in a peeling liquid such as an organic solvent. Accordingly, the partition wall 31 may be formed. Examples of the inorganic materials capable of being used for the partition wall 31 may include SiO₂, SiN, and SiON. In the case where the partition wall 31 is made of the foregoing inorganic material, the partition wall 31 is formed by forming a film made of the inorganic material by a CVD method, and subsequently shaping the resultant in a predetermined shape by a photolithography method and a wet etching method. The partition wall 31 may be formed, for example, as follows. First, a film of SiO₂ is formed by a CVD method. Subsequently, a resist having a desired pattern that is shaped in a predetermined shape by a photolithography method is formed thereon. Next, with the use of the resist as a mask, the SiO₂ film is soaked in hydrofluoric acid to perform etching. Thereafter, the resist is removed by exposing to O₂ plasma or dissolving the resist in a peeling liquid such as an organic solvent. Accordingly, the partition wall 31 may be formed. Examples of organic materials capable of being used for the partition wall 31 may include a photosensitive resin. Examples of the photosensitive resin may include a polyimide resin, a polyamide resin, an acryl resin, a novolak resin, and a polyhydroxy styrene resin. In the case where the partition wall 31 is made of the foregoing organic material, the partition wall 31 may be formed, for example, by applying a photosensitive resin, shaping the resultant in a predetermined shape by a photolithography method, and heating and curing the shaped photosensitive resin.

Cross-sectional shapes (cross-sectional shapes in the column direction) of the partition wall 31 and the insulating layer 23 may satisfy, for example, the following Formulas (1) to (3).

θ1≧90 deg (1)

tan θ3=h/x (2)

θ2<θ3 <θ1 (3)
θ1: an angle (a tilt angle of the side surface of the partition wall 31) made by the side surface and the bottom surface (the top surface of the auxiliary electrode 30) of the partition wall 31
θ2: an angle (a tilt angle of the side surface (the internal surface) of the pixel opening 23A) made by the side surface (the internal surface) of the pixel opening 23A and the pixel electrode 22
θ3: an angle made by a line segment joining the edge of the top surface of the partition wall 31 and the edge of the organic light emission layer 24 in contact with the bottom surface of the contact opening 23B; and the bottom surface (the top surface of the auxiliary electrode 30) of the contact opening 23B
h: a height of the partition wall 31 from the bottom surface (the top surface of the auxiliary electrode 30)
x: a distance between a point where a line segment vertically-elongated from the edge of the top surface of the partition wall 31 to the bottom surface (the top surface of the auxiliary electrode 30) of the contact opening 23B intersects with the bottom surface of the contact opening 23B (the top surface of the auxiliary electrode 30); and the edge of the organic light emission layer 24 in contact with the bottom surface of the contact opening 23B

In the case where the cross-sectional shapes of the partition wall 31 and the insulating layer 23 satisfy the foregoing Formulas (1) to (3), the side surfaces (the internal surfaces) of the pixel opening 23A are tapered, and the side surfaces of the partition wall 31 are tapered or vertical. Further, the side surfaces (the internal surfaces) of the pixel opening 23A are tilted aslant more than the side surfaces of the partition wall 31. Therefore, for example, by performing oblique evaporation at the angle of θ3, the organic light emission layer 24 is allowed to be formed on the whole bottom surface of the pixel opening 23A while the contact region 30A is formed behind the partition wall 31.

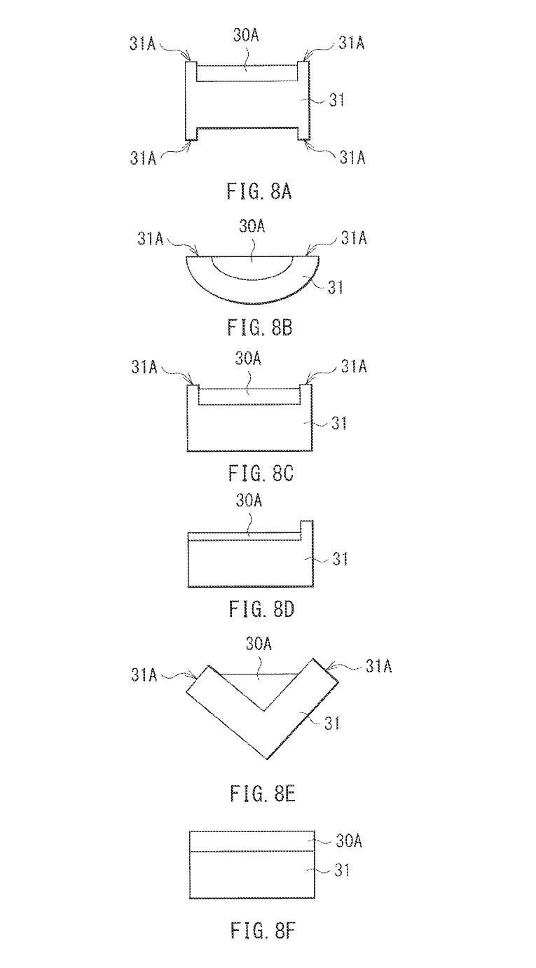

Next, description will be given of a planar shape of the partition wall 31. FIG. 8A to FIG. 8F illustrate examples of the planar shape of the partition wall 31. The partition wall 31 is formed in contact with one or more sides of the contact region 30A. In the case where the contact region 30A is square-shaped, the partition wall 31 may be formed in contact with one or more sides of the contact region 30A. In the case where the contact region 30A is square-shaped, the partition wall 31 may be formed, for example, in contact with only one side of the contact region 30A. At this time, the planar shape of the partition wall 31 may be, for example, square-shaped as illustrated in FIG. 8F. Further, in the case where the contact region 30A is square-shaped, the partition wall 31 may be formed, for example, in contact with only two sides of the contact region 30A. At this time, the planar shape of the partition wall 31 may have, for example, an alphabet “L”-like shape as illustrated in FIG. 8D. Further, in the case where the contact region 30A is square-shaped, the partition wall 31 may be formed, for example, in contact with only three sides of the contact region 30A. At this time, the planar shape of the partition wall 31 may have, for example, an alphabet “H”-like shape or an alphabet “U”-like shape as illustrated in FIG. 8A or FIG. 8C.

In the case where the contact region 30A is circular, semicircular, oval, or semielliptical, the partition wall 31 is formed in contact with a curved side of the contact region 30A. At this time, the planar shape of the partition wall 31 may have, for example, an alphabet “C”-like shape as illustrated in FIG. 8B. In the case where the contact region 30A is triangular, the partition wall 31 is formed in contact with two sides of the contact region 30A. At this time, the planar shape of the partition wall 31 may have, for example, an alphabet “V”-like shape as illustrated in FIG. 8E.

In the plane, the partition wall 31 may be preferably formed to surround part of the contact region 30A in a range from 180 deg to a value less than 360 deg. The partition walls 31 described in FIG. 8A, FIG. 8B, FIG. 8C, and FIG. 8E meet the foregoing condition. Further, for example, as illustrated in FIG. 8A, FIG. 8B, FIG. 8C, or FIG. 8E, the partition wall 31 may preferably have convex sections 31A projecting in two directions other than 180 deg in the plane direction. In the case where the partition wall 31 has such convex sections 31A, the partition wall 31 is less likely to be peeled off even if the partition wall 31 is in contact with the opposing substrate 29 or the black matrix 28 with the transparent electrode 25 in between. It is to be noted that, although the foregoing “part of the contact region 30A” is not particularly limited, for example, such part of the contact region 30A may be a position of the center of gravity in the planar shape of the contact region 30A.

### [Manufacturing Method]

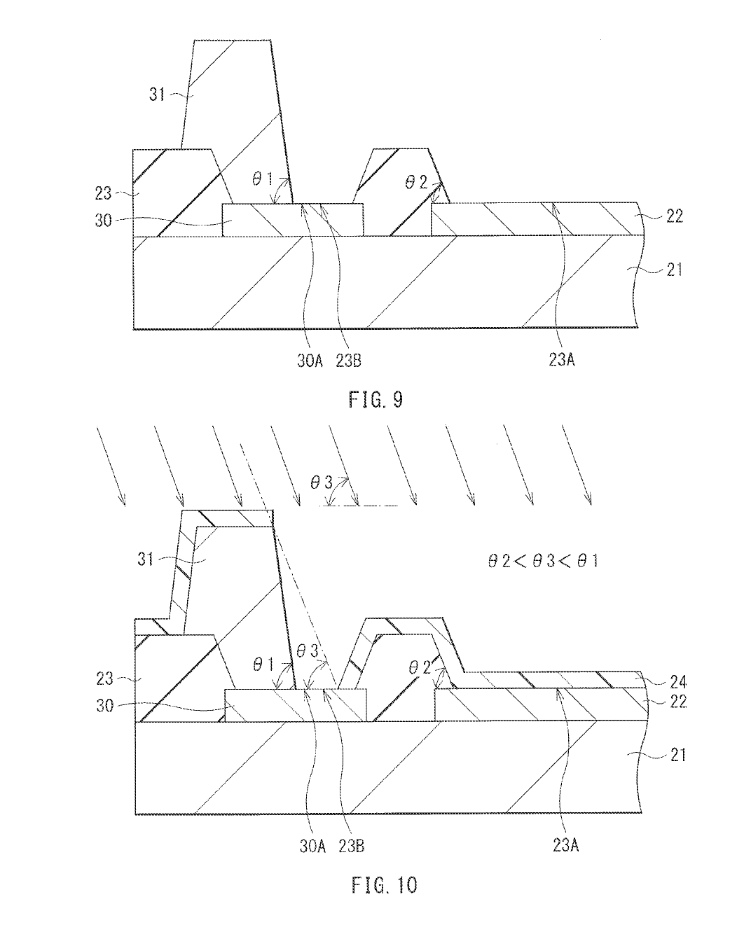

Next, description will be given of an example of methods of manufacturing the display unit 1 according to this embodiment. FIG. 9 to FIG. 11 are cross-sectional views illustrating an example of processes of manufacturing the display unit 1 in the order of processes. First, after a metal material film is formed on the circuit substrate 21 by a vapor-phase deposition method (such as a sputtering method), the resultant film is shaped in a predetermined shape by a photolithography method and etching. Thereby, the pixel electrode 22 and the auxiliary electrode 30 are formed on the circuit substrate 21 (see FIG. 9). It is to be noted that the pixel electrode 22 and the auxiliary electrode 30 may be formed in different processes by a method similar to the foregoing method.

Next, after the whole surface including the pixel electrode 22 and the auxiliary electrode 30 is coated with a photosensitive insulating resin such as polyimide, exposure and development with the use of photolithography are performed. Thereby, the pixel opening 23A is formed on the pixel electrode 22, and the contact opening 23B is formed on the auxiliary electrode 30 (see FIG. 9). Next, after the whole surface of the insulating layer 23 having the pixel opening 23A and the contact opening 23B is coated with a photosensitive insulating resin such as polyimide, exposure and development with the use of photolithography are performed. Thereby, the partition wall 31 is formed in a region from part of the bottom surface of the contact opening 23B to the side surface of the contact opening 23B and to the top surface of the insulating layer 23 (FIG. 9). At this time, the thickness of the photosensitive insulating resin, the exposure intensity, and the like may be preferably adjusted so that the cross-sectional shapes of the partition wall 31 and the insulating layer 23 satisfy the foregoing Formulas (1) to (3).

Next, the organic light emission layer 24 may be formed on the whole surface by a vapor-phase deposition method (such as an oblique evaporation method) (FIG. 10). At this time, an entrance direction of a material of the organic light emission layer 24 with respect to the top surface of the auxiliary electrode 30 is set so that a region where the contact region 30A is to be formed becomes behind (be hidden behind) the partition wall 31. Further, an incident angle of the material of the organic light emission layer 24 with respect to the top surface of the auxiliary electrode 30 (or the pixel electrode 22) may be preferably set to the angle θ3. As a result, the organic light emission layer 24 is allowed to be formed on the whole top surface of the pixel electrode 22 exposed on the bottom surface of the pixel opening 23A while part of the top surface of the auxiliary electrode 30 is exposed on the bottom surface of the contact opening 23B (that is, while the contact region 30A is formed).

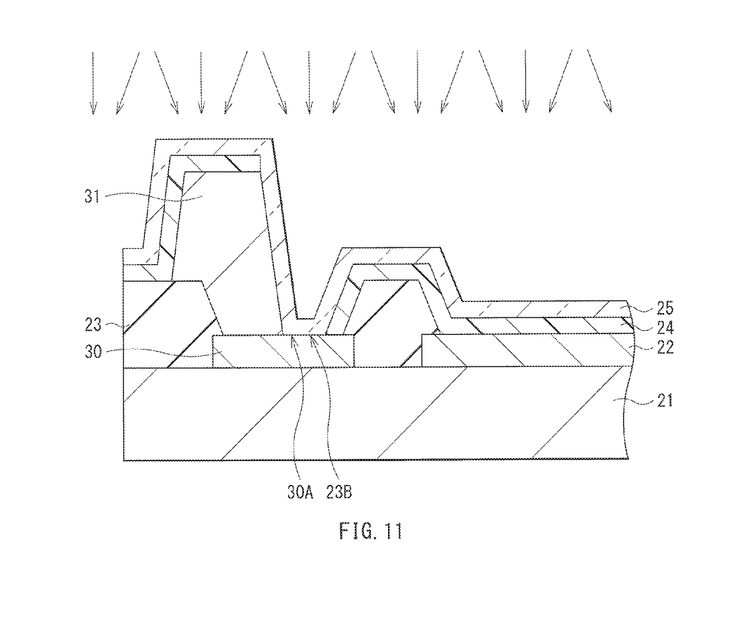

Next, for example, the transparent electrode 25 may be formed on the whole surface by a vapor-phase deposition method in which deflection of an incident angle is decreased compared to the vapor-phase deposition method used at the time of forming the organic light emission layer 24 (FIG. 11). Thereby, in the contact region 30A, the auxiliary electrode 30 and the transparent electrode 25 are allowed to be electrically connected to each other. It is to be noted that, in the evaporation method, as a method of decreasing deflection of incident angle compared to the vapor-phase deposition method used at the time of forming the organic light emission layer 24, for example, a method in which the circuit substrate 21 is laid on a rotating table, and the circuit substrate 21 is rotated may be used. Alternatively, a sputtering method may be used instead of the evaporation method. Thereby, the material of the organic light emission layer 24 is allowed to enter the circuit substrate 21 from various directions. Thereafter, for example, the transparent electrode 25 is coated with a photosensitive insulating resin such as polyimide, following which the opposing substrate 29 is attached to the photosensitive insulating resin with the color filter 27 and the black matrix 28 in between, and the photosensitive insulating resin is cured. Accordingly, the display unit 1 is manufactured.

### [Effect]

Next, description will be given of effects in the display unit 1 according to this embodiment.

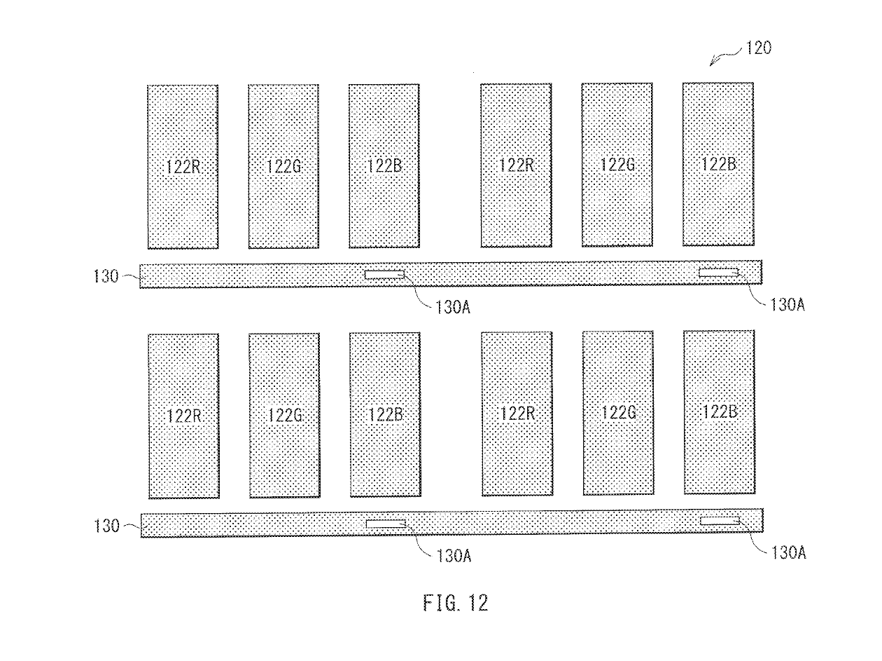

FIG. 12 illustrates an example of a layout of pixel electrodes 122R, 122G, and 122B, an auxiliary wiring 130, and a contact region 130A in a pixel region 120 of a display panel according to a comparative example. It is to be noted that the pixel electrodes 122R, 122G, and 122B corresponds to the pixel electrodes 22R, 22G, and 22B according to this embodiment. The auxiliary wiring 130 correspond to the auxiliary wiring 30 according to this embodiment. The contact region 130A is part of the top surface of the auxiliary wiring 130, and may be, for example, a region that is not covered with an insulating layer but is exposed out of the contact region 130A.

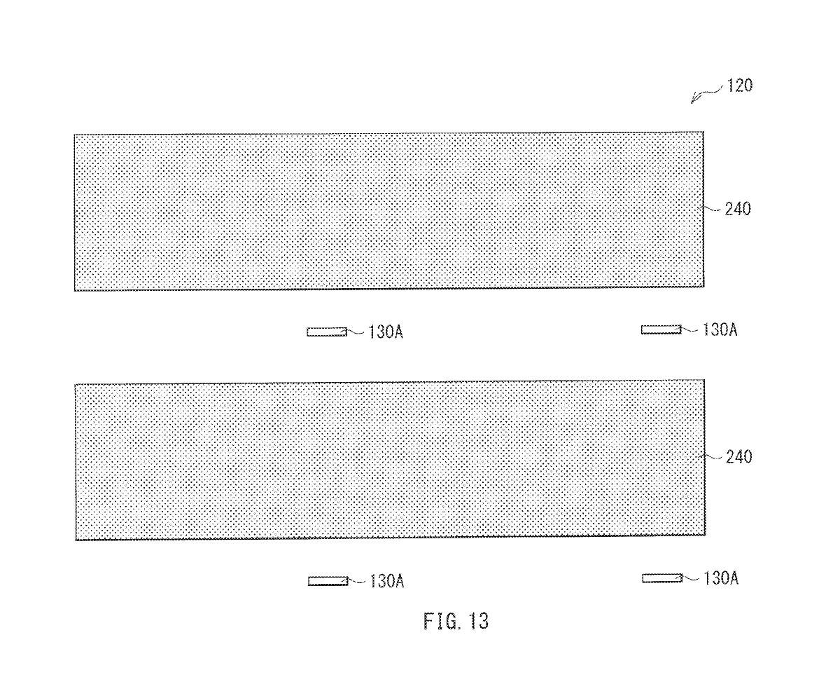

In this comparative example, as a method of electrically connecting a transparent electrode corresponding to the transparent electrode 25 according to this embodiment to the auxiliary wiring 130, for example, the transparent electrode may be formed on the contact region 130A in a manner similar to the method described in JP2002-318566A. In this case, upon forming an organic light emission layer 240 before a process of forming the transparent electrode, it is necessary to locate the formation region of the organic light emission layer on a place far from the contact region so that the organic light emission layer 240 is not formed in the contact region 130A (FIG. 13). One reason for this is that, in this case, electric connection between the contact region 130A and the transparent electrode is secured. However, in such a case, the formation region of the organic light emission layer 240 is decreased, and the aperture ratio is decreased.

Therefore, in a manner similar to the methods described in JP2007-73323A and JP2007-103098A, a contact region may be formed by wholly forming the organic light emission layer and subsequently removing part thereof. However, in such a case, yield may be lowered resulting from a residue in a process of removing the organic light emission layer.

In contrast, in this embodiment, the partition wall 31 is arranged in contact with part of the bottom surface of the contact opening 23B on the auxiliary wiring 30 and the insulating layer 23. Thereby, for example, by forming the organic light emission layer 24 by a vapor-phase deposition method (such as an evaporation method), the organic light emission layer 24 is allowed to be formed on the surface including the bottom surface of the pixel opening 23A while the contact region 30A is formed behind (is hidden behind) the partition wall 31. That is, a mask is not necessitated for preventing formation of the organic light emission layer 24 in the contact region 30A. Further, since a mask is not necessitated for forming the contact region 30A, a margin for accuracy of a mask, a position gap of a mask, and the like is not necessitated around the contact region 30A. Therefore, the pixel electrode 22 and the organic light emission layer 24 are allowed to be formed wider for the unnecessary margin. Therefore, the contact region 30A is allowed to be formed without utilizing the process of removing the organic light emission layer 24, and the aperture ratio is allowed to be increased.

Further, in this embodiment, the partition wall 31 is arranged in contact with part of the bottom surface of the contact opening 23B on the auxiliary wiring 30 and the insulating layer 23. Thereby, compared to a case in which the partition wall 31 is arranged in contact with only the auxiliary wiring 30, the partition wall 31 is less likely to be peeled off. For example, in the case where both the insulating layer 23 and the partition wall 31 are made of organic materials (hydrophobic materials), adhesibility between the insulating layer 23 and the partition wall 31 is high, and the partition wall 31 is allowed to be less likely to be peeled off. Further, for example, in the case where both the insulating layer 23 and the partition wall 31 are made of inorganic materials (hydrophilic materials), adhesibility between the insulating layer 23 and the partition wall 31 and adhesibility between the pixel electrode 22 and the partition wall 31 are high, and the partition wall 31 is allowed to be less likely to be peeled off. Further, for example, in the case where material types (a hydrophobic material and a hydrophilic material) of the insulating layer 23 and the partition wall 31 are different from each other, and the partition wall 31 is made of a metal material (a hydrophilic metal material) or an inorganic material (a hydrophilic metal material), adhesibility between the pixel electrode 22 and the partition wall 31 is high, and adhesibility between the insulating layer 23 and the partition wall 31 is comparatively high. Therefore, in this case, the partition wall 31 is allowed to be less likely to be peeled off as well. It is to be noted that in the case where a metal material (a hydrophilic metal material) or an inorganic material (a hydrophilic material) is coated with an organic material (a hydrophobic material), adhesibility between the metal material or the inorganic material and the organic material may be inhibited by a function of a surfactant contained in the organic material. Therefore, in the case where the insulating layer 23 is made of an inorganic material (a hydrophilic material), and the partition wall 31 is made of an organic material (a hydrophobic material), adhesibility between the insulating layer 23 and the partition wall 31 and adhesibility between the pixel electrode 22 and the partition wall 31 are not much high. In this case, however, by shaping the partition wall 31 into a planar shape that is hardly peeled off as described in FIG. 8A, FIG. 8B, FIG. 8C, and FIG. 8E in order to offset insufficient adhesibility between the insulating layer 23 and the partition wall 31, peeling of the partition wall 31 is allowed to be suppressed. Further, in this embodiment, the side surfaces of the pixel opening 23A are tilted aslant more than the side surfaces of the partition wall 31. Thereby, for example, in the case where the organic light emission layer 24 is formed by a vapor-phase deposition method (such as an evaporation method), the organic light emission layer 24 is allowed to be formed on (is allowed to be in contact with) the whole bottom surface of the pixel opening 23A.

Further, in this embodiment, in the case where the partition wall 31 is formed to surround part of the contact region 30A in a range from 180 deg to a value less than 360 deg in the plane, the partition wall 31 is allowed to be less likely to be peeled off Further, even if the partition wall 31 is miniaturized, adhesion of the material of the organic light emission layer 24 to the contact region 30A is allowed to be effectively blocked. As a result, the aperture ratio is allowed to be increased for the effect obtained by miniaturizing the partition wall 31. Further, in the case where the partition wall 31 has the convex sections 31A projecting in two directions other than 180 deg in the plane direction, the partition wall 31 is also allowed to be less likely to be peeled off. In the case where the partition wall 31 has a structure in which the partition wall 31 is allowed to be less likely to be peeled off as described above, for example, upon forming the transparent electrode 25 by a vapor-phase deposition method, the amount of the material of the transparent electrode 25 entering into the contact region 30A is decreased, and a resistance value in the contact region 30A is easily increased. Therefore, in this case, the thickness of the transparent electrode 25 may be increased. In this embodiment, in the case where the transparent electrode 25 is made of a light-transmissive electrically-conductive material containing one or both of Ca and Li, lowering of light transmissibility (transparency) of the transparent electrode 25 is allowed to be suppressed even if the thickness of the transparent electrode 25 is increased. As a result, while lowering of optical characteristics of the display unit 1 is suppressed, increase of the resistance value in the contact region 30A is allowed to be suppressed, and image quality of the display unit 1 is allowed to be improved.

### 2. Modifications

Description will be given below of various modifications of the display unit 1 according to the foregoing embodiment. In the following description, for the same components as those of the display unit 1 of the foregoing embodiment, the same referential symbols are affixed thereto. Further, for the same components as those of the display unit 1 of the foregoing embodiment, description thereof will be omitted as appropriate.

### Modification 1

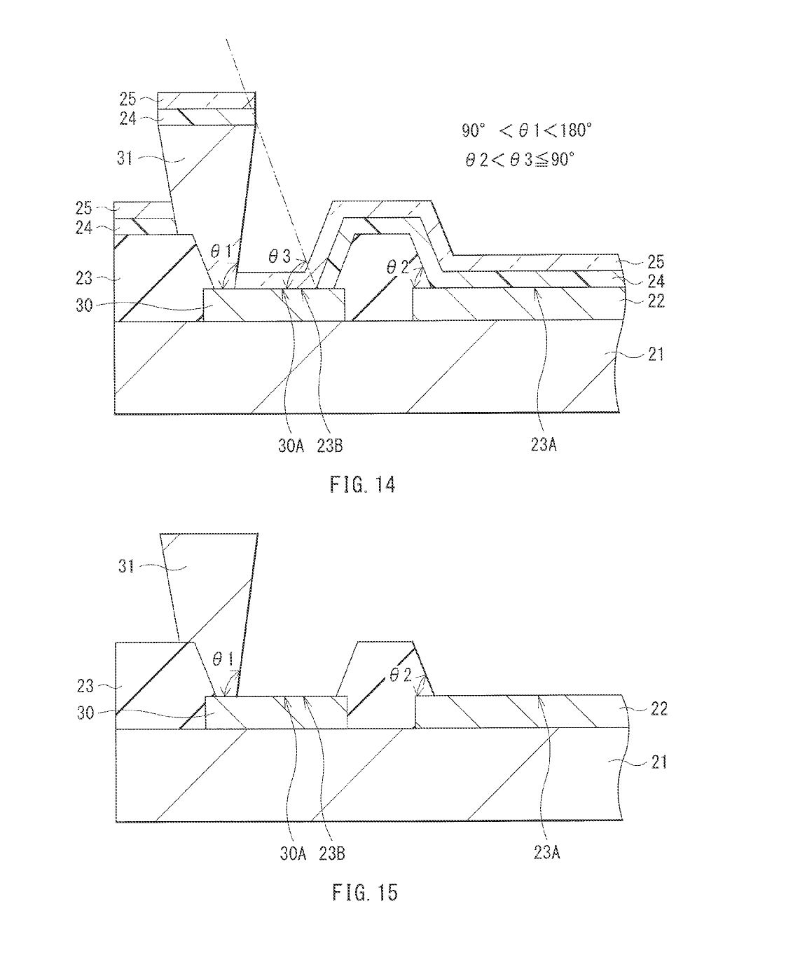

In the foregoing embodiment, the case in which the side surfaces of the partition wall 30 are tapered has been exemplified. However, the side surfaces of the partition wall 30 may be inversely-tapered, for example, as illustrated in FIG. 14. At this time, cross-sectional shapes of the partition wall 31 and the insulating layer 23 may satisfy, for example, the foregoing Formula (2) and the following Formulas (4) and (5).

90 deg<θ1<180 deg (4)

θ2<θ3<90 deg (5)

In the case where the cross-sectional shapes of the partition wall 31 and the insulating layer 23 satisfy the foregoing Formulas (2), (4), and (5), a gap exists under a side surface of the partition wall 31, and the bottom surface of the gap becomes the contact region 30A. Further, the side surface (the internal surface) of the pixel opening 23A is tilted aslant more than the line segment joining the edge of the top surface of the partition wall 31 and the edge of the organic light emission layer 24 in contact with the bottom surface of the contact opening 23B. Therefore, by performing oblique evaporation at the angle of θ3 or performing evaporation from a direction perpendicular to the top surface of the pixel electrode 22, the organic light emission layer 24 is allowed to be formed on the whole bottom surface of the pixel opening 23A while the contact region 30A is formed behind the partition wall 31.

Next, description will be given of an example of methods of manufacturing the display unit 1 according to this modification. FIG. 15 to FIG. 17 are cross-sectional views illustrating an example of processes of manufacturing the display unit 1 in the order of processes. It is to be noted that processes until forming the insulating layer 23 are similar to those of the foregoing embodiment, and therefore, processes after forming the insulating layer 23 will be described below.

After forming the insulating layer 23, the whole surface of the insulating layer 23 having the pixel opening 23A and the contact opening 23B is coated with a photosensitive insulating resin such as polyimide. Subsequently, exposure and development with the use of photolithography are performed. Thereby, the partition wall 31 is formed in a region from part of the bottom surface of the contact opening 23B to the side surface of the contact opening 23B and to the top surface of the insulating layer 23 (FIG. 15). At this time, the thickness of the photosensitive insulating resin, the exposure intensity, and the like may be preferably adjusted so that the cross-sectional shapes of the partition wall 31 and the insulating layer 23 satisfy the foregoing Formulas (2), (4), and (5).

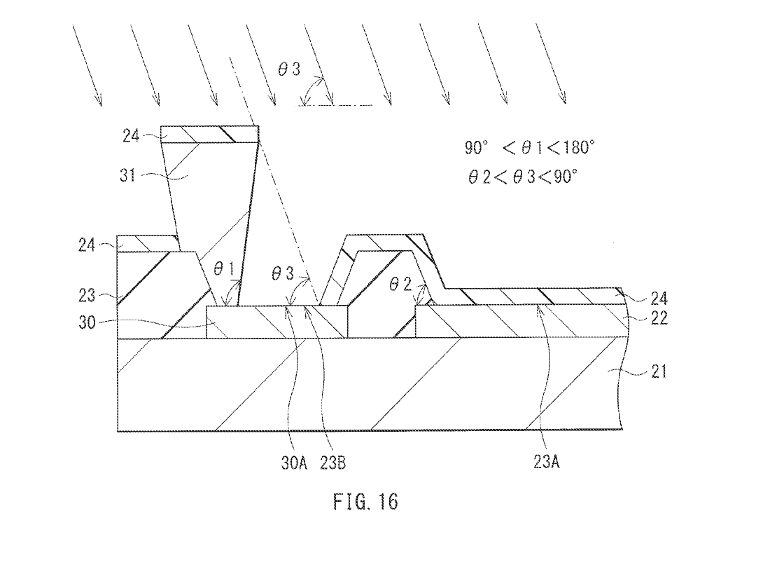

Next, for example, the organic light emission layer 24 may be formed on the whole surface by a vapor-phase deposition method (such as an oblique evaporation method) (FIG. 16). At this time, an entrance direction of a material of the organic light emission layer 24 with respect to the top surface of the auxiliary electrode 30 is set so that a region where the contact region 30A is to be formed becomes behind (be hidden behind) the partition wall 31. Further, an incident angle of the material of the organic light emission layer 24 with respect to the top surface of the auxiliary electrode 30 (or the pixel electrode 22) may be preferably set to the angle θ3. As a result, the organic light emission layer 24 is allowed to be formed on the whole top surface of the pixel electrode 22 exposed on the bottom surface of the pixel opening 23A while part of the top surface of the auxiliary electrode 30 is exposed on the bottom surface of the contact opening 23B (that is, while the contact region 30A is formed).

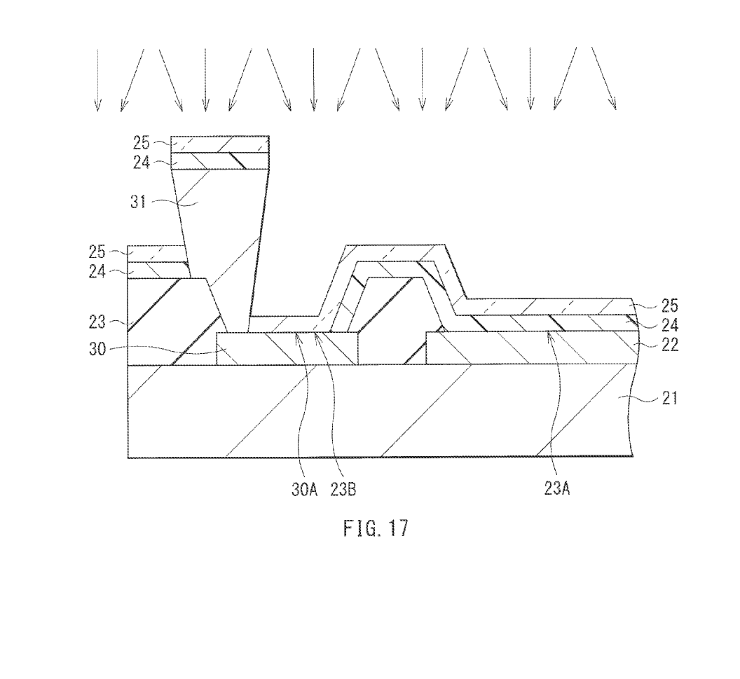

Next, for example, the transparent electrode 25 may be formed on the whole surface by a vapor-phase deposition method in which deflection of an incident angle is decreased compared to the vapor-phase deposition method used at the time of forming the organic light emission layer 24 (FIG. 17). Thereby, in the contact region 30A, the auxiliary electrode 30 and the transparent electrode 25 are allowed to be electrically connected to each other. It is to be noted that, in the evaporation method, as a method of decreasing deflection of an incident angle compared to the vapor-phase deposition method used at the time of forming the organic light emission layer 24, for example, a method in which the circuit substrate 21 is laid on a rotating table, and the circuit substrate 21 is rotated may be used. Alternatively, a sputtering method may be used instead of the evaporation method. Thereby, the material of the organic light emission layer 24 is allowed to enter the circuit substrate 21 from various directions. Thereafter, for example, the transparent electrode 25 is coated with a photosensitive insulating resin such as polyimide, following which the opposing substrate 29 is attached to the photosensitive insulating resin with the color filter 27 and the black matrix 28 in between, and the photosensitive insulating resin is cured. Accordingly, the display unit 1 according to this modification is manufactured.

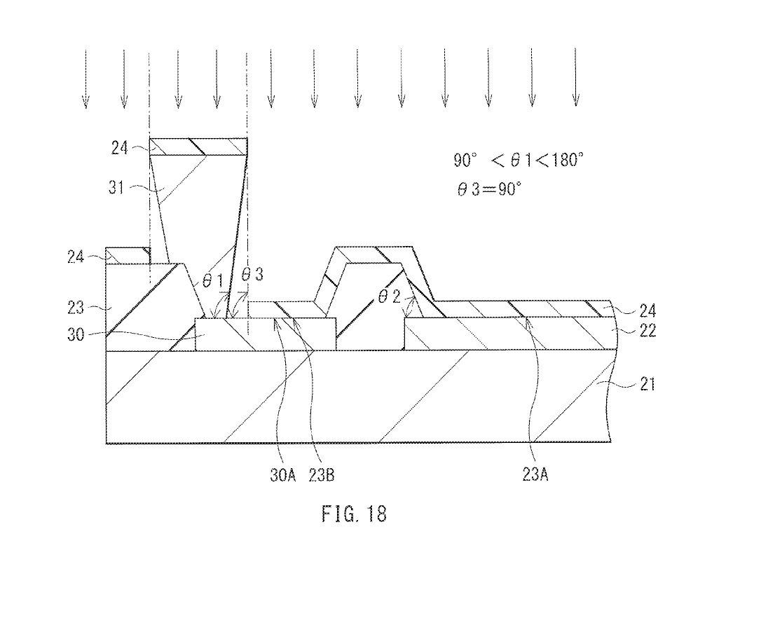

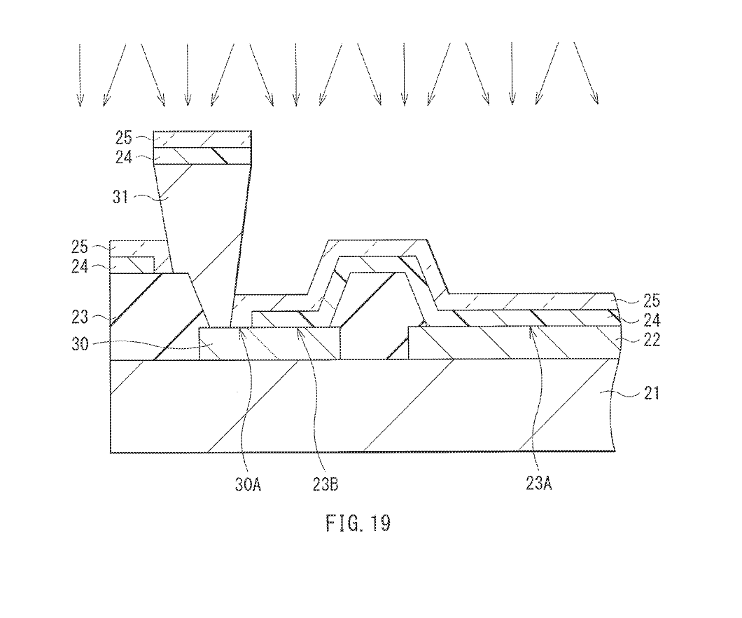

The display unit 1 according to this modification may be also manufactured in the following method. FIG. 18 and FIG. 19 are cross-sectional views illustrating another example of processes of manufacturing the display unit 1 according to this modification in the order of processes. It is to be noted that processes until forming the partition wall 31 are similar to those of the foregoing manufacturing method, and therefore, description will be given below of processes after forming the partition wall 31.

After forming the partition wall 31, for example, the organic light emission layer 24 may be formed on the whole surface by a vapor-phase deposition method (such as an evaporation method) (FIG. 18). For example, a main incident angle of the material of the organic light emission layer 24 may be set perpendicular to the auxiliary electrode 30 (or the pixel electrode 22). That is, as a vapor-phase deposition method, a vertical evaporation method is used. At this time, the material of the organic light emission layer 24 is less likely to enter into a portion under the inversely-tapered side surface of the partition wall 31. Therefore, out of the contact opening 23B, a portion corresponding to the portion under the inversely-tapered side surface of the partition wall 31 becomes the contact region 30A. Therefore, the organic light emission layer 24 is allowed to be formed on the whole top surface of the pixel electrode 22 exposed on the bottom surface of the pixel opening 23A while part of the top surface of the auxiliary electrode 30 is exposed on the bottom surface of the contact opening 23B (that is, while the contact region 30A is formed).

Next, for example, the transparent electrode 25 may be formed on the whole surface by a vapor-phase deposition method in which deflection of an incident angle is decreased compared to the vapor-phase deposition method used at the time of forming the organic light emission layer 24 (FIG. 19). Thereby, in the contact region 30A, the auxiliary wiring 30 and the transparent electrode 25 are allowed to be electrically connected to each other. It is to be noted that, in the evaporation method, as a method of decreasing deflection of an incident angle compared to the vapor-phase deposition method used at the time of forming the organic light emission layer 24, for example, a method in which the circuit substrate 21 is laid on a rotating table, and the circuit substrate 21 is rotated may be used. Alternatively, a sputtering method may be used instead of the evaporation method. Thereby, the material of the transparent electrode 25 is allowed to enter the circuit substrate 21 from various directions. Thereafter, for example, the transparent electrode 25 may be coated with a photosensitive insulating resin such as polyimide, following which the opposing substrate 29 may be attached to the photosensitive insulating resin with the color filter 27 and the black matrix 28 in between, and the photosensitive insulating resin may be cured. Accordingly, the display unit 1 according to this modification is manufactured.

### Modification 2

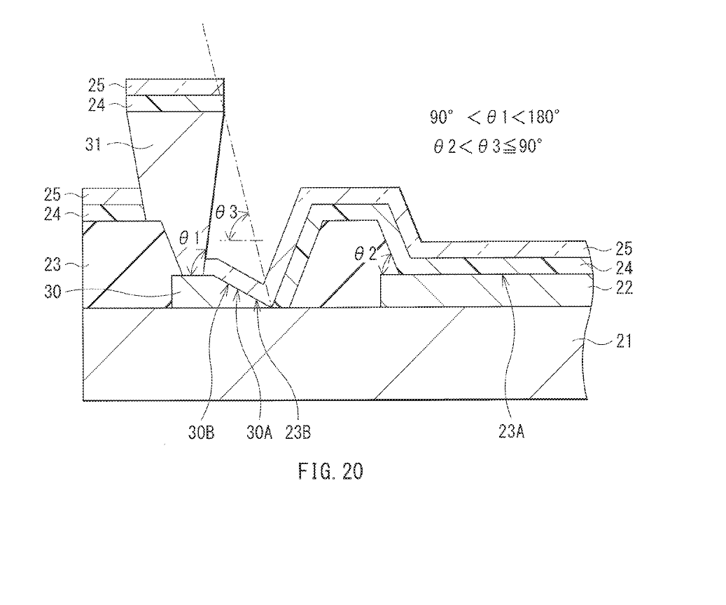

In the foregoing Modification 1, the top surface of the auxiliary electrode 30 is a flat surface. However, for example, as illustrated in FIG. 20, a portion (the contact region 30A) exposed on the bottom surface of the contact opening 23B out of the top surface of the auxiliary wiring 30 may be a tilted surface 30B. The tilted surface 30B is formed to be downward-sloping more with distance from the side surface of the partition wall 31. An angle made by the tilted surface 30B and the side surface of the partition wall 31 may be preferably about 90 deg, and may be slightly larger than 90 deg. The tilted surface 30B may be a smooth surface, or a stepped surface. The circuit substrate 21 is a flat surface in a portion under a portion where the tilted surface 30B is formed in the auxiliary wiring 30. In the auxiliary wiring 30, the thickness thereof in the portion where the tilted surface 30B is formed is smaller than the thickness thereof in other portions. As a method of forming the tilted surface 30B in the auxiliary wiring 30, for example, partial etching of the top surface of the auxiliary wiring 30 may be used.

In this modification, the portion exposed on the bottom surface of the contact opening 23B out of the top surface of the auxiliary wiring 30 is the tilted surface 30B. Thereby, for example, in the case where the transparent electrode 25 is formed on the whole surface by a vapor-phase deposition method in which deflection of an incident angle is decreased compared to the vapor-phase deposition method used at the time of forming the organic light emission layer 24, the transparent electrode 25 having a sufficient thickness is allowed to be formed in the contact region 30A. As a result, in the contact region 30A, electric connection between the auxiliary electrode 30 and the transparent electrode 25 is further secured.

### Modification 3

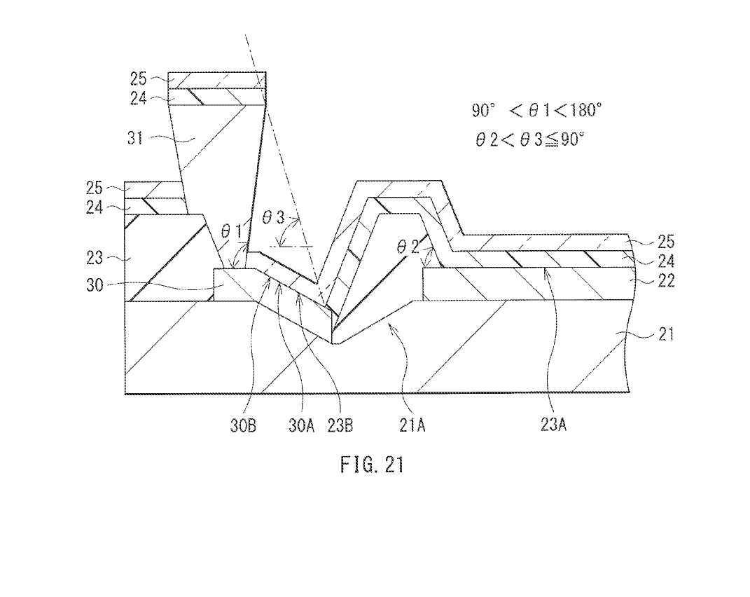

In the foregoing Modification 2, by providing the tilted surface 30B in the auxiliary wiring 30, the portion exposed on the bottom surface of the contact opening 23B out of the top surface of the auxiliary wiring 30 becomes the tilted surface 30B. However, for example, as illustrated in FIG. 21, a mortar-like recessed portion 21A may be provided in a portion under the bottom surface of the contact opening 23B out of the top surface of the circuit substrate 21, and part of the auxiliary wiring 30 may be arranged inside the mortar-like recessed portion 21A. In this case, the portion exposed on the bottom surface of the contact opening 23B out of the top surface of the auxiliary wiring 30 is allowed to become the tilted surface 30B as well.

That is, in this modification, the circuit substrate 21 has the mortar-like recessed portion 21A in the portion under the bottom surface of the contact opening 23B. Further, part of the auxiliary wiring 30 is arranged inside the mortar-like recessed portion 21A. At this time, the thickness of the auxiliary wiring 30 is uniform without depending on locations. Therefore, in this modification, the portion exposed on the bottom surface of the contact opening 23B out of the top surface of the auxiliary wiring 30 is allowed to become the tilted surface 30B while the thickness of the auxiliary wiring 30 is kept substantially uniform without depending on locations.

### Manufacturing Method

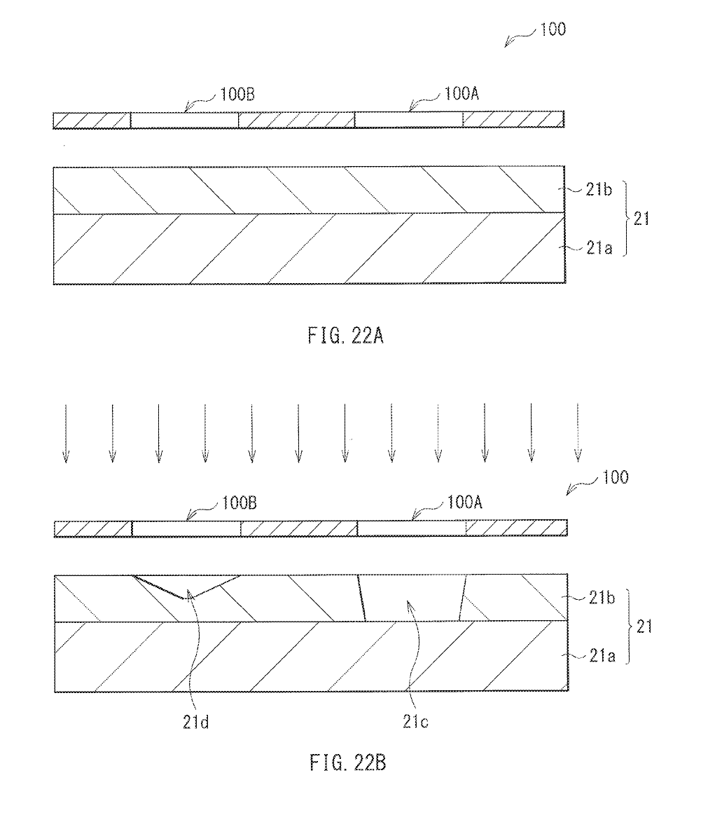

Next, description will be given of an example of methods of manufacturing the display unit 1 according to this modification. FIG. 22A and FIG. 22B are cross-sectional views illustrating an example of processes of manufacturing the display unit 1 according to this modification in the order of processes. It is to be noted that, in this modification, the circuit substrate 21 has a planarizing film 21b on a circuit substrate 21a on which the pixel circuit 15 is formed. The planarizing film 21b may be made, for example, of a material capable of being subjected to exposure and development by photolithography, and may be made, for example, of a photosensitive insulating resin.

First, a mask 100 having an opening 100A and a gray tone opening 100B in predetermined positions is arranged on the circuit substrate 21 (FIG. 22A). The opening 100A is a through hole that penetrates through the mask 100. The gray tone opening 100B has a structure in which transmittance of ultraviolet light is lower than that of the through hole. Next, for example, with the use of the mask 100, exposure by photolithography is performed, and subsequently, image development is performed (FIG. 22B). Thereby, in one exposure, a recessed portion 21d having a shallow depth and a recessed portion 21C having a deep depth are allowed to be formed in the planarizing film 21b at the same time. It is to be noted that the recessed portion 21d may be used as the recessed portion 21A, and the recessed portion 21C may be used, for example, as a location into which a via that electrically connects the pixel circuit 15 to the pixel electrode 22 is buried.

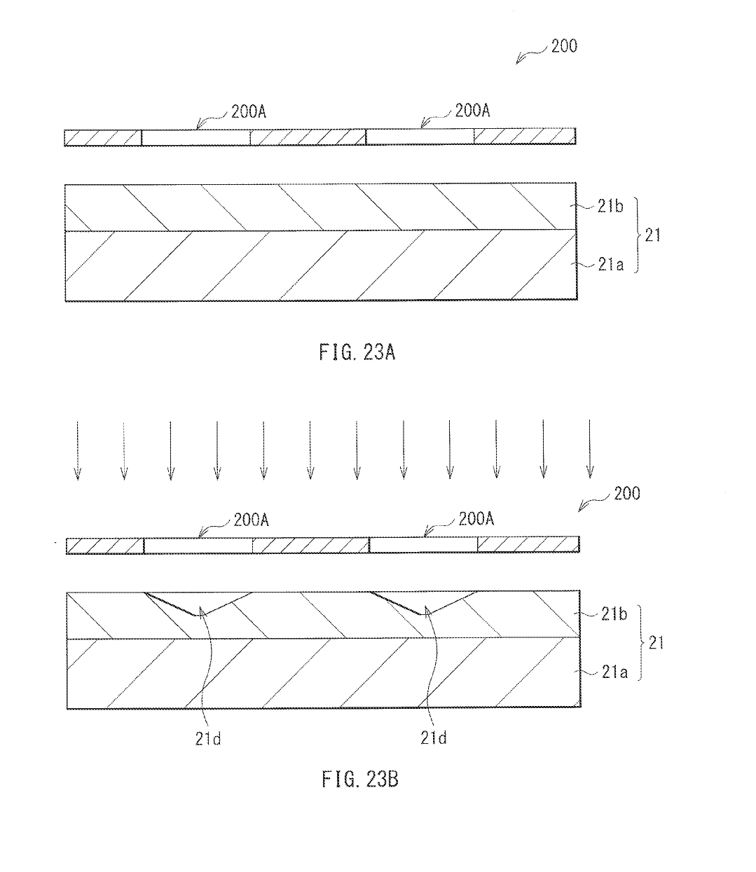

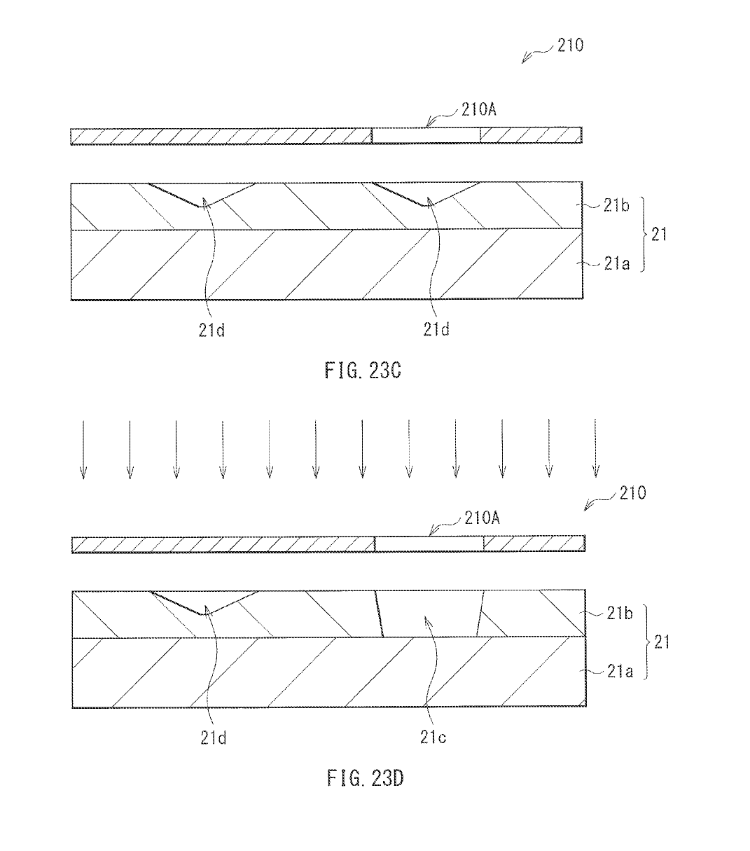

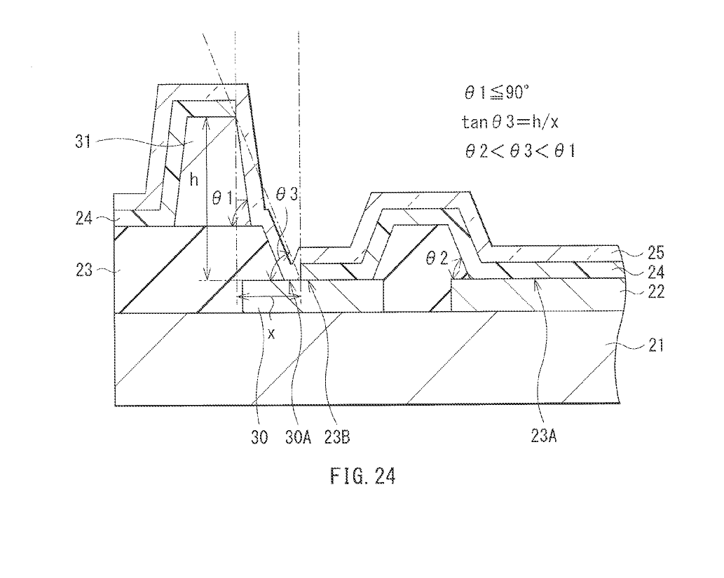

The display unit 1 according to this modification may be manufactured, for example, by the following method. FIG. 23A, FIG. 23B, FIG. 23C, and FIG. 24D are cross-sectional views illustrating another example of processes of manufacturing the display unit 1 according to this modification in the order of processes.

First, a mask 200 having two openings 200A in predetermined positions is arranged on the circuit substrate 21 (FIG. 23A). The opening 200A is a through hole that penetrates through the mask 200. Next, for example, with the use of the mask 200, exposure by photolithography is performed, and subsequently, development is performed (FIG. 23B). Thereby, two recessed portions 21d having a shallow depth are allowed to be formed in the planarizing film 21b. Next, a mask 210 having one opening 210A above one recessed portion 21d is arranged on the circuit substrate 21 (FIG. 23C). The opening 210A is a through hole that penetrates through the mask 210. Next, for example, with the use of the mask 210, exposure by photolithography is performed, and subsequently, development is performed (FIG. 23D). Thereby, the recessed portion 21d under the opening 210A is further deepened to become the recessed portion 21c. As described above, in two exposures, the recessed portion 21d having a shallow depth and the recessed portion 21c having a deep depth are allowed to be formed in the planarizing film 21b. It is to be noted that the recessed portion 21d may be used as the recessed portion 21A, and the recessed portion 21c may be used, for example, as a location into which a via that electrically connects the pixel circuit 15 to the pixel electrode 22 is buried.

### Modification 4

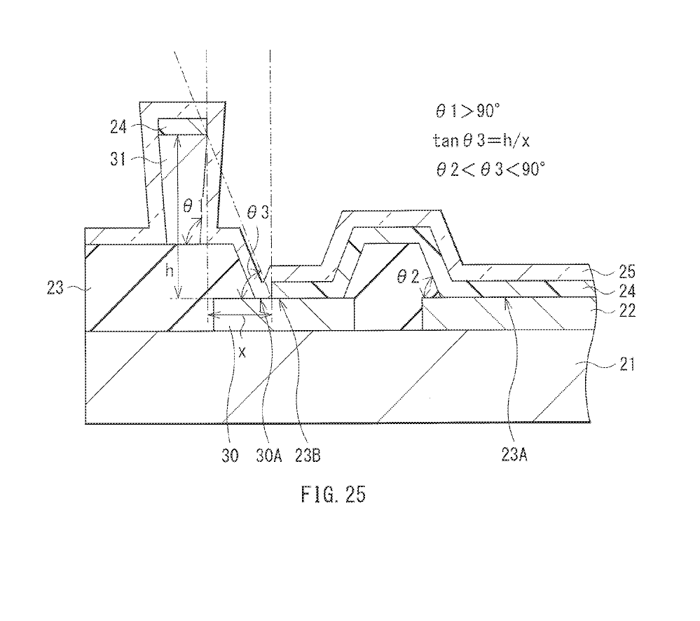

In the foregoing embodiment and the modifications thereof (Modifications 1 to 3), the partition wall 31 is in contact with all of part of the non-contact region 30a, the adjacent side surface 30b, and the adjacent top surface 30c. However, the partition wall 31 may be in contact with only the adjacent side surface 30b and the adjacent top surface 30c. Further, for example, as illustrated in FIG. 24 and FIG. 25, the partition wall 31 may be in contact with only the adjacent top surface 30c. However, as illustrated in FIG. 24, in the case where the side surfaces of the partition wall 31 are tapered or vertical, the cross-sectional shapes of the partition wall 31 and the insulating layer 23 may satisfy, for example, the foregoing Formula (1) to Formula (3). Further, as illustrated in FIG. 25, in the case where the side surfaces of the partition wall 30 are inversely-tapered, the cross-sectional shapes of the partition wall 31 and the insulating layer 23 may satisfy, for example, the foregoing Formulas (2), (4), and (5).

In the case where the cross-sectional shapes of the partition wall 31 and the insulating layer 23 satisfy the foregoing Formula (1) to Formula (3), for example, by performing oblique evaporation at the angle of θ3, the organic light emission layer 24 is allowed to be formed on the whole bottom surface of the pixel opening 23A while the contact region 30A is formed behind the partition wall 31. Further, in the case where the cross-sectional shapes of the partition wall 31 and the insulating layer 23 satisfy the foregoing Formulas (2), (4), and (5), for example, by performing oblique evaporation at the angle of θ3 or performing evaporation from a direction perpendicular to the top surface of the pixel electrode 22, the organic light emission layer 24 is allowed to be formed on the whole bottom surface of the pixel opening 23A while the contact region 30A is formed behind the partition wall 31.

### Modification 5

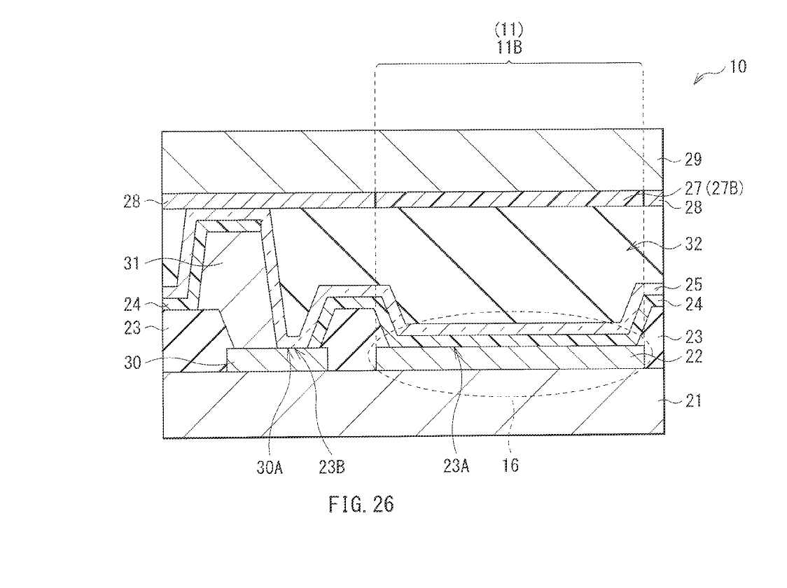

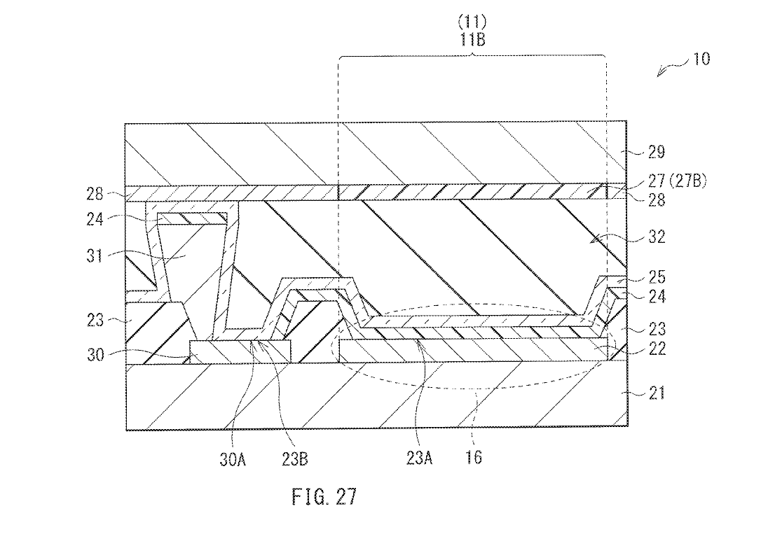

In the foregoing embodiment and the modifications thereof (Modifications 1 to 4), the insulating layer 26 is provided to be buried in the gap between the circuit substrate 21 and the opposing substrate 29. However, for example, as illustrated in FIG. 26 and FIG. 27, a gap 32 may exist between the circuit substrate 21 and the opposing substrate 29. At this time, the partition wall 31 may be in contact with the opposing substrate 29 or the black matrix 28 with the transparent electrode 25 in between, or may be formed low to the degree that the partition wall 31 is not in contact with the opposing substrate 29 or the black matrix 28. In the case where the partition wall 31 is in contact with the opposing substrate 29 or the black matrix 28 with the transparent electrode 25 in between, for example, as illustrated in FIG. 8A, FIG. 8B, FIG. 8C, or FIG. 8E, the partition wall 31 may preferably have the convex sections 31A projecting in two directions other than 180 deg in the plane direction. In the case where the partition wall 31 has such convex sections 31A, the partition wall 31 is less likely to be peeled off even if the partition wall 31 is in contact with the opposing substrate 29 or the black matrix 28 with the transparent electrode 25 in between. Further, the partition wall 31 may be preferably formed to surround part of the contact region 30A in a range from 180 deg to a value less than 360 deg in the plane. The partition walls 31 described in FIG. 8A, FIG. 8B, FIG. 8C, and FIG. 8E meet the foregoing condition. In such a case, for example, in the case where the organic light emission layer 24 is formed by an evaporation method, the organic light emission layer 24 is allowed to be prevented from entering into the contact region 30A, and in addition thereto, the partition wall 31 is allowed to be less likely to be peeled off by the foregoing function of the convex sections.

### Modification 6

In the foregoing embodiment and the modifications thereof (Modifications 1 to 5), the organic light emission layer 24 emits white light. However, the organic light emission layer 24 may separately emit light of different colors (such as red light, green light, and blue light). For example, as illustrated in FIG. 28, the organic light emission layer 24 may have an organic light emission layer 24B that emits blue light common to the pixel 11R, the pixel 11G, and the pixel 11B. Further, for example, as illustrated in FIG. 28, the organic light emission layer 24 may have an organic light emission layer 24R that emits red light in a region corresponding to the pixel 11R on the organic light emission layer 24B, and may have an organic light emission layer 24G that emits green light in a region corresponding to the pixel 11G on the organic light emission layer 24B. It is to be noted that the organic light emission layer 24B may be provided only in a region corresponding to the pixel 11B.

In the case where the display panel 10 has a stripe alignment, the organic light emission layer 24R is in the shape of a strip that is formed continuously in the column direction and steps over the plurality of pixels 11R (the pixel electrodes 22R). Further, the organic light emission layer 24G is in the shape of a strip that is formed continuously in the column direction and steps over the plurality of pixels 11G (the pixel electrodes 22G). Thereby, upon performing separate coating of the organic light emission layer 24R and the organic light emission layer 24G, it is not necessary to perform alignment in the column direction of a mask at a pixel 11 level. Such alignment in the column direction of a mask is not necessarily performed at the pixel 11 level, whether the contact region 30A and the partition wall 31 are arranged in a gap between two pixels 11 adjacent to each other in the column direction or in a gap between two color pixels adjacent to each other in the row direction.

### Modification 7

In the foregoing embodiment and the modifications thereof (Modifications 1 to 6), the display panel 10 is a color display panel. However, the display panel 10 may be a monochrome display panel. For example, as illustrated in FIG. 29, in the display panel 10, the color filter 27 may be omitted in the configuration illustrated in FIG. 3.

### Modification 8

In the foregoing embodiment and the modifications thereof (Modifications 1 to 6), the display panel 10 has a stripe alignment. However, the display panel 10 may have any other alignment. For example, in the case where each color pixel is configured of four pixels 11 emitting four-color light separately, the four pixels 11 included in each color pixel may be aligned, for example, in a two-by-two matrix pattern.

### 3. Application Examples

Description will be given below of application examples of the display unit 1 described in the foregoing embodiment and the modifications thereof (Modifications 1 to 8) (hereinafter referred to as “the foregoing embodiment or the like”). The display unit 1 according to the foregoing embodiment or the like is applicable to a display unit of an electronic apparatus in any field for displaying an image signal inputted from outside or an image signal generated inside as an image or a video. Examples of the electronic apparatus may include a television, a digital camera, a notebook personal computer, a portable terminal device such as a mobile phone, and a video camcorder.

### Application Example 1

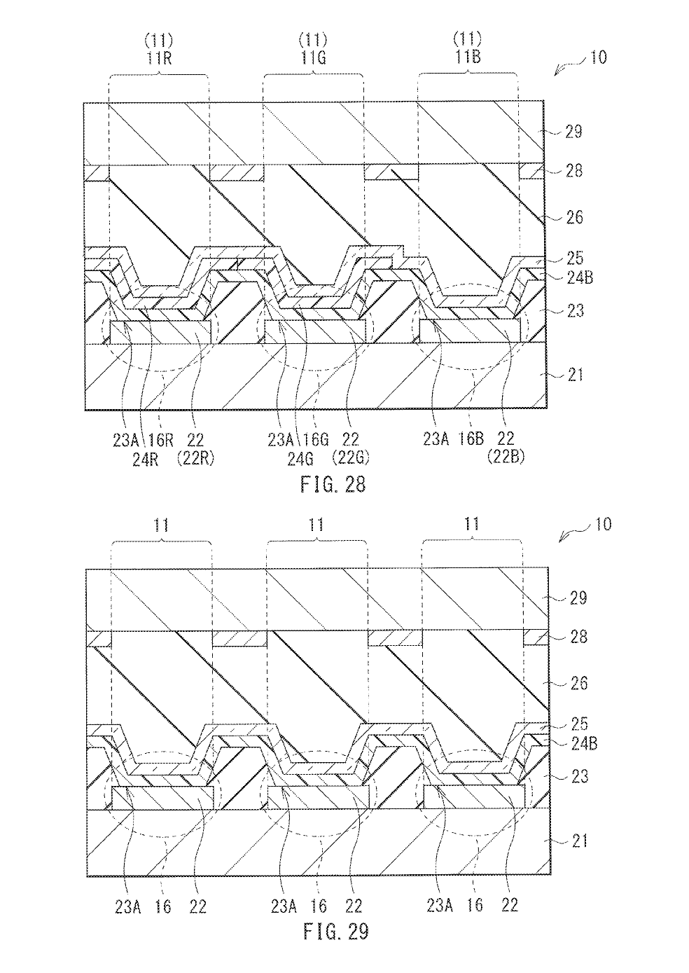

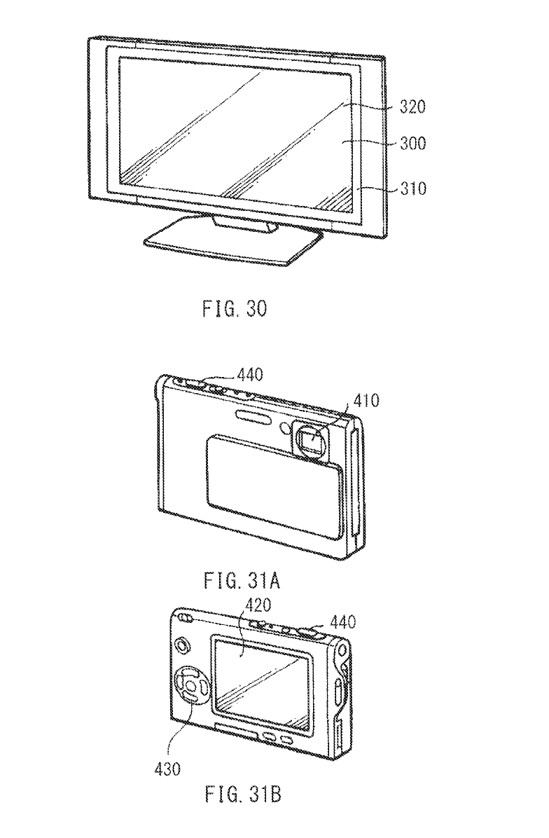

FIG. 30 illustrates an appearance of a television to which the display unit 1 according to the foregoing embodiment or the like is applied. The television may have, for example, an image display screen section 300 including a front panel 310 and a filter glass 320. The image display screen section 300 is configured of the display unit 1 according to the foregoing embodiment or the like.

### Application Example 2

FIG. 31A and FIG. 31B illustrate appearances of a digital camera to which the display unit 1 according to the foregoing embodiment or the like is applied. The digital camera may have, for example, a light emitting section 410 for a flash, a display section 420, a menu switch 430, and a shutter button 440. The display section 420 is configured of the display unit 1 according to the foregoing embodiment or the like.

### Application Example 3

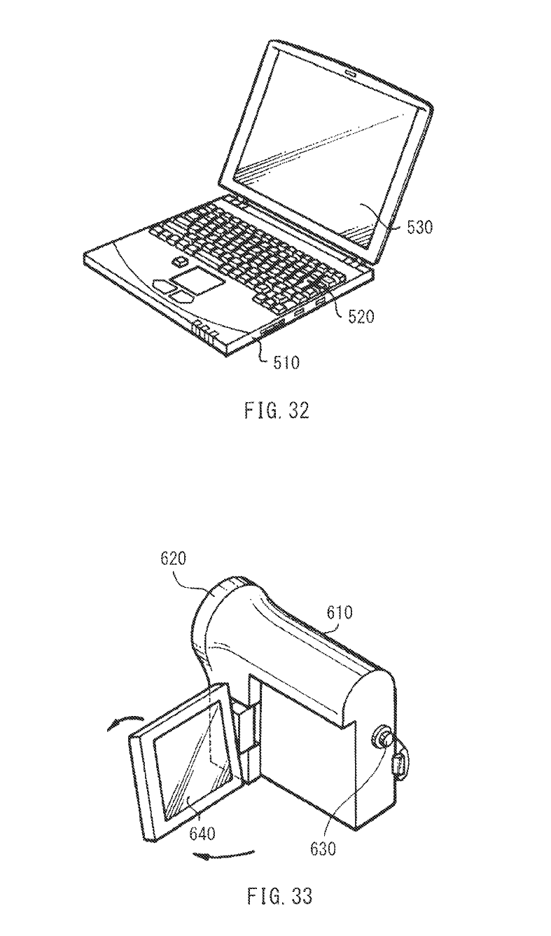

FIG. 32 illustrates an appearance of a notebook personal computer to which the display unit 1 according to the foregoing embodiment or the like is applied. The notebook personal computer may have, for example, a main body 510, a keyboard 520 for operation of inputting characters and the like, and a display section 530 for displaying an image. The display section 530 is configured of the display unit 1 according to the foregoing embodiment or the like.

### Application Example 4

FIG. 33 illustrates an appearance of a video camcorder to which the display unit 1 according to the foregoing embodiment or the like is applied. The video camcorder may have, for example, a main body 610, a lens 620 for shooting a subject provided on the front side surface of the main body 610, a start-stop switch 630 for shooting, and a display section 640. The display section 640 is configured of the display unit 1 according to the foregoing embodiment or the like.

### Application Example 5

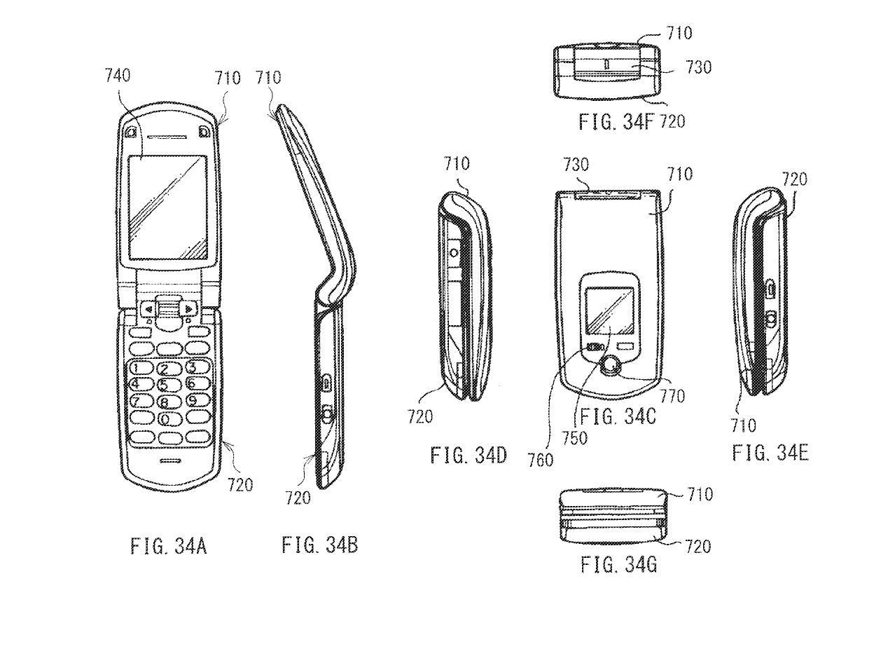

FIG. 34A to FIG. 34F illustrate appearances of a mobile phone to which the display unit 1 according to the foregoing embodiment or the like is applied. In the mobile phone, for example, an upper package 710 and a lower package 720 may be coupled by a joint section (a hinge section) 730. The mobile phone may have a display 740, a sub-display 750, a picture light 760, and a camera 770. Either one or both of the display 740 and the sub-display 750 are configured of the display unit 1 according to the foregoing embodiment or the like.

While the present technology has been described with reference to the embodiment and the application examples, the present technology is not limited to the foregoing embodiment or the like, and various modifications may be made.

For example, a configuration of the pixel circuit 15 for active matrix drive is not limited to the configurations described in the foregoing embodiment or the like, and a capacitor or a transistor may be added as necessary in the foregoing embodiment or the like. In this case, along with change of the pixel circuit 15, a necessary drive circuit other than the foregoing signal line drive circuit 13, the scanning line drive circuit 14, and the like may be added.

Furthermore, the technology encompasses any possible combination of some or all of the various embodiments described herein and incorporated herein.

It is possible to achieve at least the following configurations from the above-described example embodiments of the disclosure.
(1) A display unit including:

a plurality of first electrodes;

a metal member provided around the first electrodes;

an insulating layer having a first opening on corresponding one of the first electrodes and a second opening on the metal member;

an organic light emission layer provided on a surface including a bottom surface of the first opening, except for whole or part of a bottom surface of the second opening;

a partition wall arranged in contact with at least the insulating layer out of part of the bottom surface of the second opening and the insulating layer, the partition wall being formed in a process different from a process of forming the insulating layer; and

a second electrode provided in contact with a contact region and in contact with a portion above the bottom surface of the first opening in the organic light emission layer, the contact region being part of the bottom surface of the second opening.
(2) The display unit according to (1), wherein the partition wall is in contact with both the part of the bottom surface of the second opening and the insulating layer.
(3) The display unit according to (1) or (2), wherein a side surface of the first opening is tilted aslant more than a side surface of the partition wall.
(4) The display unit according to any one of (1) to (3), wherein the partition wall is formed to surround part of the contact region in a range from about 180 degrees to a value less than about 360 degrees in a plane.
(5) The display unit according to any one of (1) to (4), wherein the partition wall includes convex sections projecting in two directions other than 180 degrees in a plane direction.
(6) The display unit according to any one of (1) to (5), wherein the partition wall is arranged to be opposed to corresponding one of the first electrodes with the contact region in between in a plane.
(7) The display unit according to any one of (1) to (6), wherein

the organic light emission layer has a shape of a strip that is formed continuously in a column direction and steps over the plurality of first electrodes, and

the contact region and the partition wall are arranged in a gap between two of the plurality of first electrodes adjacent to each other in the column direction.
(8) The display unit according to any one of (1) to (7), wherein the second electrode is made of a light-transmissive electrically-conductive material containing one or both of Ca and Li.
(9) The display unit according to any one of (1) to (8), wherein the contact region is formed to be downward-sloping more with distance from a side surface of the partition wall.
(10) An electronic apparatus provided with a display unit, the display unit including:

a plurality of first electrodes;

a metal member provided around the first electrodes;

an insulating layer having a first opening on corresponding one of the first electrodes and a second opening on the metal member;

an organic light emission layer provided on a surface including a bottom surface of the first opening, except for whole or part of a bottom surface of the second opening;

a partition wall arranged in contact with at least the insulating layer out of part of the bottom surface of the second opening and the insulating layer, the partition wall being formed in a process different from a process of forming the insulating layer; and

a second electrode provided in contact with a contact region and in contact with a portion above the bottom surface of the first opening in the organic light emission layer, the contact region being part of the bottom surface of the second opening.
(11) A method of manufacturing a display unit, the method including:

forming an insulating layer having a first opening on corresponding one of a plurality of first electrodes and a second opening on a metal member, the metal member being provided around the first electrodes;

forming, by a vapor-phase diffusion method, a partition wall to be in contact with at least the insulating layer out of part of a bottom surface of the second opening and the insulating layer;

forming, by a vapor-phase deposition method, an organic light emission layer on a surface including a bottom surface of the first opening, except for whole or part of the bottom surface of the second opening; and

forming, by a vapor-phase deposition method in which deflection of an incident angle is decreased compared to the vapor-phase deposition method used upon forming the organic light emission layer, a second electrode in contact with a contact region and in contact with a portion above the bottom surface of the first opening in the organic light emission layer, the contact region being part of the bottom surface of the second opening.
(12) The method of manufacturing the display unit according to (11), wherein

a side surface of the partition wall is inversely-tapered, and

a main incident angle of a material of the organic light emission layer is set perpendicular to the metal member in the forming the organic light emission layer.
(13) The method of manufacturing the display unit according to (11), wherein

a side surface of the partition wall is tapered or vertical, and

a main incident angle of a material of the organic light emission layer is set oblique with respect to the metal member in the forming the organic light emission layer.

It should be understood by those skilled in the art that various modifications, combinations, sub-combinations and alternations may occur depending on design requirements and other factors insofar as they are within the scope of the appended claims or the equivalents thereof.

What is claimed is:

1. A display unit comprising:
a plurality of first electrodes;
a metal member provided around the first electrodes;
an insulating layer having a first opening on corresponding one of the first electrodes and a second opening on the metal member;
an organic light emission layer provided on a surface including a bottom surface of the first opening, except for whole or part of a bottom surface of the second opening;
a partition wall arranged in contact with at least the insulating layer out of part of the bottom surface of the second opening and the insulating layer, the partition wall being formed in a process different from a process of forming the insulating layer; and
a second electrode provided in contact with a contact region and in contact with a portion above the bottom surface of the first opening in the organic light emission layer, the contact region being part of the bottom surface of the second opening.

2. The display unit according to claim 1, wherein the partition wall is in contact with both the part of the bottom surface of the second opening and the insulating layer.

3. The display unit according to claim 2, wherein a side surface of the first opening is tilted aslant more than a side surface of the partition wall.

4. The display unit according to claim 2, wherein the partition wall is formed to surround part of the contact region in a range from about 180 degrees to a value less than about 360 degrees in a plane.

5. The display unit according to claim 2, wherein the partition wall includes convex sections projecting in two directions other than 180 degrees in a plane direction.

6. The display unit according to claim 2, wherein the partition wall is arranged to be opposed to corresponding one of the first electrodes with the contact region in between in a plane.

7. The display unit according to claim 6, wherein
the organic light emission layer has a shape of a strip that is formed continuously in a column direction and steps over the plurality of first electrodes, and
the contact region and the partition wall are arranged in a gap between two of the plurality of first electrodes adjacent to each other in the column direction.

8. The display unit according to claim 2, wherein the second electrode is made of a light-transmissive electrically-conductive material containing one or both of Ca and Li.

9. The display unit according to claim 2, wherein the contact region is formed to be downward-sloping more with distance from a side surface of the partition wall.

10. An electronic apparatus provided with a display unit, the display unit comprising:
a plurality of first electrodes;
a metal member provided around the first electrodes;
an insulating layer having a first opening on corresponding one of the first electrodes and a second opening on the metal member;
an organic light emission layer provided on a surface including a bottom surface of the first opening, except for whole or part of a bottom surface of the second opening;
a partition wall arranged in contact with at least the insulating layer out of part of the bottom surface of the second opening and the insulating layer, the partition wall being formed in a process different from a process of forming the insulating layer; and
a second electrode provided in contact with a contact region and in contact with a portion above the bottom surface of the first opening in the organic light emission layer, the contact region being part of the bottom surface of the second opening.

11. A method of manufacturing a display unit, the method comprising:
forming an insulating layer having a first opening on corresponding one of a plurality of first electrodes and a second opening on a metal member, the metal member being provided around the first electrodes;
forming, by a vapor-phase diffusion method, a partition wall to be in contact with at least the insulating layer out of part of a bottom surface of the second opening and the insulating layer;
forming, by a vapor-phase deposition method, an organic light emission layer on a surface including a bottom surface of the first opening, except for whole or part of the bottom surface of the second opening; and
forming, by a vapor-phase deposition method in which deflection of an incident angle is decreased compared to the vapor-phase deposition method used upon forming the organic light emission layer, a second electrode in contact with a contact region and in contact with a portion above the bottom surface of the first opening in the organic light emission layer, the contact region being part of the bottom surface of the second opening.

12. The method of manufacturing the display unit according to claim 11, wherein
a side surface of the partition wall is inversely-tapered, and
a main incident angle of a material of the organic light emission layer is set perpendicular to the metal member in the forming the organic light emission layer.

13. The method of manufacturing the display unit according to claim 11, wherein
a side surface of the partition wall is tapered or vertical, and
a main incident angle of a material of the organic light emission layer is set oblique with respect to the metal member in the forming the organic light emission layer.
